(19) United States
(12) Patent Application Publication
(10) Pub. No.: US 2024/0258065 A1
(43) Pub. Date: Aug. 1, 2024

(54) METHOD OF OPERATING A PARTICLE BEAM SYSTEM AND COMPUTER PROGRAM PRODUCT

(71) Applicant: Carl Zeiss Microscopy GmbH, Jena (DE)

(72) Inventors: Dirk Preikszas, Oberkochen (DE); Kai Wicker, Jena (DE); Bjoern Gamm, Koenigsbronn (DE); Yauheni Novikau, Apolda (DE); Ralf Wolleschensky, Jena (DE)

(21) Appl. No.: 18/424,034

(22) Filed: Jan. 26, 2024

(30) Foreign Application Priority Data
Jan. 27, 2023 (DE) 10 2023 102 073.0

(51) Int. Cl. H01J 37/21; G06T 7/00; H01J 37/09; H01J 37/145; H01J 37/147; H01J 37/153; H01J 37/22; H01J 37/28

(52) U.S. Cl. CPC H01J 37/21; G06T 7/0002; H01J 37/09; H01J 37/145; H01J 37/1472; H01J 37/153; H01J 37/222; H01J 37/28; G06T 2207/10148; G06T 2207/20221; H01J 2237/0451; H01J 2237/0458; H01J 2237/1534; H01J 2237/24578

(57) ABSTRACT

Particle beam systems, for example electron beam microscopes, exhibit improved resolution in a first direction by manipulating a beam of charged particles so that the beam has a non-circular beam profile in a focal plane of an objective lens. Multiple images of a sample can be recorded at different orientations of the beam profile relative to the sample, and the recorded images can be synthesized using non-uniform spatial-frequency weights to obtain an image of the sample having improved resolution in any direction. The orientation of the beam profile can be adjusted to a target orientation depending on a structure on a sample prior to recording an image of the sample, thereby making it possible to achieve highest resolution in a selected direction of interest.

### CROSS-REFERENCE TO RELATED APPLICATION

This application claims benefit under 35 U.S.C. § 119 to German Application No. 10 2023 102 073.0, filed Jan. 27, 2023. The entire disclosure of this application is incorporated by reference herein.

### FIELD

The present disclosure relates to particle beam systems and methods for operating the same. Further, the present disclosure relates to a computer program product for executing the method on a particle beam system.

### BACKGROUND

Some conventional particle beam systems comprise a particle source for generating a beam of charged particles, an aperture stop having a circular aperture limiting the beam laterally, an objective lens focusing the beam into a focal plane, a detector detecting interaction products of the beam with a sample located in the focal plane and outputting a detection signal according to the detected interaction products, and a controller controlling the particle beam system and evaluating the detection signal to generate an image of the sample.

However, the focusing of the beam by the objective lens can cause spherical aberration and chromatic aberration. For conventional certain electron beam microscopes, the energy width of the beam can have values in the order of 0.3 eV to 0.7 eV for specific particle sources of high performance, while particle sources with an energy width of the beam of up to 3 eV are in use. Accordingly, chromatic aberration can be the dominant contribution to a total aberration of the beam in the focal plane. In this case, chromatic aberration can be the dominant contribution to limited resolution. In general, the smaller the total aberration of the beam in the focal plane, the better the resolution.

For reducing the chromatic aberration of the focusing of the beam by the objective lens, a conventional corrector can be used. A conventional corrector is illustrated in FIG. 1. This conventional corrector has four sequentially arranged multipole field generators each configured to generate a multipole field for manipulating the beam of charged particles. A collimated beam having a circular cross-section enters the first multipole field parallel to a z-direction which coincides with an optical axis of the conventional corrector. The first multipole field focuses the beam in an x-direction and defocuses the beam in a y-direction.

The second multipole field is arranged in z-direction at a focal plane for the x-direction of the first multipole field. The second multipole field has an electric quadrupole field and a magnetic quadrupole field superimposed on each other. The second multipole field only weakly affects the beam in the x-direction because the beam crosses the optical axis at the second multipole field. The second multipole field focuses the beam in the y-direction thereby correcting a chromatic aberration in the y-direction of a subsequent objective lens.

The third multipole field is arranged in z-direction at a focal plane for the y-direction of the second multipole field. The third multipole field has an electric quadrupole field and a magnetic quadrupole field superimposed on each other. The third multipole field only weakly affects the beam in the y-direction because the beam crosses the optical axis at the third multipole field. The third multipole field focuses the beam in the x-direction thereby correcting a chromatic aberration in the x-direction of the subsequent objective lens.

The fourth multipole field defocuses the beam in the x-direction and focuses the beam in the y-direction thereby generating a collimated beam having a circular cross-section.

### SUMMARY

The above-described conventional corrector has a relatively complex structure and can be difficult to adjust and to operate. Further, the conventional corrector can be relatively expensive, e.g., due to the large number of electric and magnetic fields to be generated and to be adjusted. The conventional corrector is also relatively large.

The present disclosure seeks to provide a relatively simpler and relatively inexpensive particle beam system capable of recording an image of a sample.

A first aspect of the disclosure relates to a method of operating a particle beam system, the method comprising: generating a beam of charged particles; focusing the beam into a focal plane by an objective lens; manipulating the beam into a beam profile in which a ratio of a first interaction length to a second interaction length amounts to at most 1:1.2, wherein the first interaction length is a distance, measured along a first direction, between a first straight line perpendicular to the first direction and a second straight line perpendicular to the first direction, wherein the first straight line defines a first half-plane, wherein the first half-plane is located in the focal plane and contains 25% of a total intensity of the beam in the focal plane, wherein the second straight line defines a second half-plane, wherein the second half-plane is located in the focal plane and contains 25% of the total intensity of the beam in the focal plane and does not overlap the first half-plane, wherein the second interaction length is a distance, measured along a second direction different from the first direction, between a third straight line perpendicular to the second direction and a fourth straight line perpendicular to the second direction, wherein the third straight line defines a third half-plane, wherein the third half-plane is located in the focal plane and contains 25% of the total intensity of the beam in the focal plane, wherein the fourth straight line defines a fourth half-plane, wherein the fourth half-plane is located in the focal plane and contains 25% of the total intensity of the beam in the focal plane and does not overlap the third half-plane; adjusting an orientation of the beam profile in the focal plane relative to a sample to a target orientation; recording an image of the sample located in the focal plane using the manipulated beam having the adjusted orientation; repeating the adjusting and the recording with at least one other target orientation different from the previously used target orientations; and calculating a synthesized image of the sample based on the recorded images.

According to the first aspect, the first interaction length, which characterizes the intensity distribution of the beam in the first direction in the focal plane, is smaller than the second interaction length, which characterizes the intensity distribution of the beam in the second direction in the focal plane. For example, the first interaction length is smaller than a corresponding interaction length of a beam generated by a conventional particle beam system not having any specific correctors. Consequently, a maximum resolution in the first direction in the image(s) recorded by the method according to the first aspect can be higher than a maximum resolution of an image recorded by a conventional particle beam system not having any specific correctors. This feature generally comes at the cost that a maximum resolution in the second direction of the image(s) recorded by the method according to the first aspect is worse than the maximum resolution of the image recorded by the conventional particle beam system not having any specific correctors. Consequently, in comparison to a conventional particle beam system not having any specific correctors, the synthesized image obtained by the method according to the first aspect can provide improved resolution in any direction.

In comparison to the conventional particle beam system having the above-described conventional corrector, a system for performing the method according to the first aspect comprises less components while providing similar functionality.

A second aspect of the disclosure relates to a method of operating a particle beam system, the method comprising: generating a beam of charged particles; focusing the beam into a focal plane by an objective lens; manipulating the beam into a beam profile in which a ratio of a first interaction length to a second interaction length amounts to at most 1:1.2, wherein the first interaction length is a distance, measured along a first direction, between a first straight line perpendicular to the first direction and a second straight line perpendicular to the first direction, wherein the first straight line defines a first half-plane, wherein the first half-plane is located in the focal plane and contains 25% of a total intensity of the beam in the focal plane, wherein the second straight line defines a second half-plane, wherein the second half-plane is located in the focal plane and contains 25% of the total intensity of the beam in the focal plane and does not overlap the first half-plane, wherein the second interaction length is a distance, measured along a second direction different from the first direction, between a third straight line perpendicular to the second direction and a fourth straight line perpendicular to the second direction, wherein the third straight line defines a third half-plane, wherein the third half-plane is located in the focal plane and contains 25% of the total intensity of the beam in the focal plane, wherein the fourth straight line defines a fourth half-plane, wherein the fourth half-plane is located in the focal plane and contains 25% of the total intensity of the beam in the focal plane and does not overlap the third half-plane; adjusting an orientation of the beam profile in the focal plane relative to a sample to a target orientation; recording an image of the sample located in the focal plane using the manipulated beam having the adjusted orientation; and selecting the target orientation based on an orientation of a structure on the sample.

According to the second aspect, similar to the first aspect, a maximum resolution in the first direction in the image recorded by the method according to the second aspect is higher than a maximum resolution of an image recorded by a conventional particle beam system not having any specific correctors. Consequently, in comparison to a conventional particle beam system not having any specific correctors, the recorded image obtained by the method according to the second aspect has an improved resolution in the target orientation which is a selected direction of particular interest.

A third aspect of the disclosure relates to a computer program product comprising instructions which, when executed by a controller of a particle beam system, causes the particle beam system to perform the method according to the first and second aspect, respectively.

### BRIEF DESCRIPTION OF THE DRAWINGS

FIG. 1 shows a schematic illustration of the conventional corrector according to the prior art.

FIG. 2 shows a schematic illustration of a particle beam system according to a first embodiment.

FIG. 3 shows a schematic illustration of a trajectory of a fundamental ray in a first plane in the particle beam system according to the first embodiment.

FIG. 4 shows a schematic illustration of the trajectory of the fundamental ray in a second plane in the particle beam system according to the first embodiment.

FIGS. 5A and 5B show a schematic illustration of a beam profile of a beam of charged particles according to the first embodiment and examples of an interaction length.

FIG. 6 shows a schematic illustration of an interaction profile of the beam profile illustrated in FIGS. 5A and 5B.

FIG. 7 shows a schematic illustration of an exemplary implementation of a first multipole field generator of the particle beam system according to the first embodiment.

FIG. 8 shows a schematic illustration of another exemplary implementation of the first multipole field generator of the particle beam system according to the first embodiment.

FIG. 9 shows a schematic illustration of a trajectory of a fundamental ray in a first plane in a particle beam system according to a second embodiment.

FIG. 10 shows a schematic illustration of the trajectory of the fundamental ray in a second plane in the particle beam system according to the second embodiment.

FIG. 11 shows a schematic illustration of a plurality of energy-specific beam-intensity-isolines in a plane OL of the particle beam system according to the second embodiment.

FIG. 12 shows a schematic illustration of a trajectory of a fundamental ray in a first plane in a particle beam system according to a third embodiment.

FIG. 13 shows a schematic illustration of the trajectory of the fundamental ray in a second plane in the particle beam system according to the third embodiment.

FIG. 14 shows a schematic illustration of an exemplary implementation of a second multipole field generator and a third multipole field generator of the particle beam system according to the third embodiment.

FIG. 15 shows a schematic illustration of another exemplary implementation of the second multipole field generator and the third multipole field generator of the particle beam system according to the third embodiment.

FIG. 16 shows a schematic illustration of a trajectory of a fundamental ray in a first plane in a particle beam system according to a fourth embodiment.

FIG. 17 shows a schematic illustration of the trajectory of the fundamental ray in a second plane in the particle beam system according to the fourth embodiment.

FIG. 18 shows a schematic illustration of a trajectory of a fundamental ray in a first plane in a particle beam system according to a fifth embodiment.

FIG. 19 shows a schematic illustration of the trajectory of the fundamental ray in a second plane in the particle beam system according to the fifth embodiment.

FIG. 20 shows a schematic illustration of a trajectory of a fundamental ray in a first plane in a particle beam system according to a sixth embodiment.

FIG. 21 shows a schematic illustration of the trajectory of the fundamental ray in a second plane in the particle beam system according to the sixth embodiment.

FIGS. 22A-22D shows a schematic illustration of a beam profile of a beam of charged particles according to the sixth embodiment and examples of interaction lengths.

FIG. 23 shows a schematic illustration of an interaction profile of the beam profile illustrated in FIGS. 22A-22D.

FIG. 24 shows a schematic illustration of another beam profile of a beam of charged particles according to the sixth embodiment.

FIG. 25 shows a flowchart illustrating a first method of operating a particle beam system according to any one of the embodiments.

FIG. 26 shows a flowchart illustrating a second method of operating a particle beam system according to any one of the embodiments.

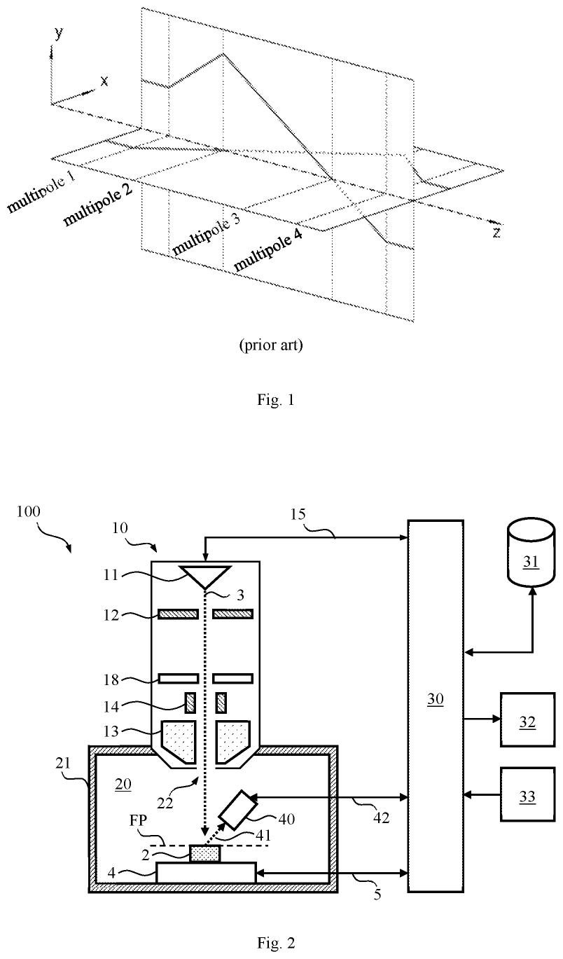

### DETAILED DESCRIPTION

Hereinafter, specific embodiments of the disclosure are described in detail with reference to the accompanying drawings. Same or similar elements in different drawings are denoted by same reference numerals.

### First Embodiment: Chromatic Aberration Correction in One Direction

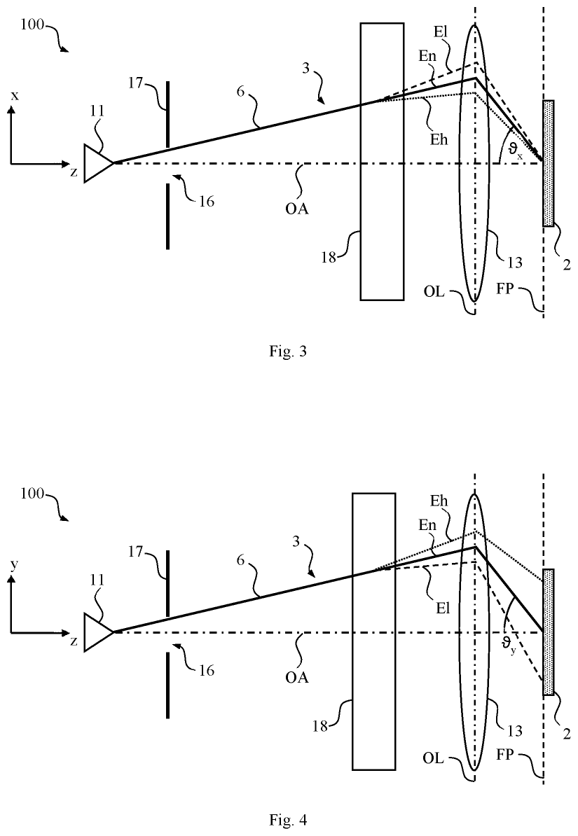

FIG. 2 shows a schematic illustration of a particle beam system 100 such as an electron beam microscope according to a first embodiment. The particle beam system 100 can be used to record an image of a sample 2.

The particle beam system 100 comprises a beam column 10 configured to generate a beam 3 of charged particles and to direct the generated beam 3 to the sample 2.

The beam column 10 comprises a particle source 11 configured to provide the charged particles of the beam 3. In case of an electron beam column, the particle source 11 is an electron source. Typically, an energy width (i.e., full width at half maximum of a histogram of kinetic energies) of an electron beam can have values in the order of 0.3 eV to 0.7 eV for specific electron sources of high performance, while electron sources providing an energy width of the electron beam of up to 3 eV are in use. In case of an ion beam column, the particle source 11 is an ion source. Typically, an energy width of an ion beam can have values in the order of up to 10 eV depending on the particular type of source. For example, a liquid metal ion source can provide an energy width of approximately 5 eV, a gas field ion source can provide an energy width of approximately 0.3 eV, and a plasma ion source can provide an energy width of approximately 10 eV.

An electric potential applied to the particle source 11 can be different from an electric potential of the sample 2, so that the charged particles of the beam 3 hit the sample 2 with a landing energy according to the difference between the electric potential of the particle source 11 and the electric potential of the sample 2.

In practice, for a scanning electron microscope, landing energies of the charged particles of the beam 3 (i.e., the kinetic energies of the charged particles of the beam 3 at impact on the sample 2) range from a low-value regime in the order of 1 keV to a high-value regime in the order of 10 keV to 20 keV.

An electric current of the charged particles of the beam 3 is selected as is typical for charged particle beam microscopes. That is, the electric current of the charged particles of the beam 3 is in the order of 1 pA to 100 pA. Accordingly, the electric current of the charged particles of the beam 3 is much less than a typical electric current of a charged particle beam of an inspection system in the art. Nevertheless, even the performance of an inspection system with a high electric current can be improved with the procedures of this disclosure.

Alternatively, the electric current of the charged particles of the beam 3 is selected as is typical for a charged particle beam of an inspection system. That is, the electric current of the charged particles of the beam 3 is in the order of 500 pA to 100 nA. In this case, the electric current of the charged particles of the beam 3 is much greater than a typical electric current of a charged particle beam of a charged particle beam microscope in the art.

The beam column 10 further comprises an acceleration electrode 12 configured to accelerate the charged particles of the beam 3 to a selectable kinetic energy in accordance with a selectable electric potential applied to the acceleration electrode 12 and the electric potential of the particle source 11. In the illustrated example, the acceleration electrode 12 is embodied by a plate electrode having an aperture through which the beam 3 propagates. In practice, for a scanning electron microscope, the charged particles of the beam 3 can be accelerated to values within 5 keV to 30 keV. For a typical transmission electron microscope, the acceleration electrode 12 is grounded and the charged particles of the beam 3 are accelerated to values above 50 keV.

The beam column 10 further comprises an objective lens 13 configured to focus the beam 3 into a focal plane FP. The objective lens 13 can be a magnetic and/or electrostatic lens, for example. The focal plane FP is indicated by a dashed line in FIG. 2. For example, the objective lens 13 spherically focuses the beam 3 into the focal plane FP. This means that the objective lens 13 focuses a collimated beam having a circular beam shape propagating parallel to an optical axis OA of the objective lens 13 into a circular spot on the focal plane FP. In this context, a beam has a circular beam shape if a beam contour corresponding to a limiting aperture stop has a circular shape. In other words, the objective lens 13 is configured to generate a focusing field acting on the beam 3, wherein the focusing field is substantially radially symmetric about the optical axis OA.

The beam column 10 further comprises a beam deflection system 14 configured to deflect the beam 3 so that the beam 3 can be directed to a plurality of locations on the sample 2. The beam deflection system 14 can be configured to deflect the beam 3 along two directions which are substantially perpendicular to each other and to an optical axis OA of the objective lens 13. In the example illustrated in FIG. 2, the optical axis OA of the objective lens 13 is parallel to the vertical axis of FIG. 2 and is located at a center of the objective lens 13. The optical axis OA of the objective lens 13 is perpendicular to the focal plane FP.

The beam column 10 further comprises a first multipole field generator 18. The first multipole field generator 18 is configured to generate a first multipole field for manipulating the beam 3. The first multipole field acts on the beam 3 downstream (i.e., in direction from the particle source 11 to the focal plane FP behind) the acceleration electrode 12. The first multipole field acts on the beam 3 upstream (i.e., in direction from the particle source 11 to the focal plane FP before) the objective lens 13. The function of the first multipole field is described further below with reference to FIGS. 3 and 4.

The beam column 10 can further comprise one or more condenser lenses (not illustrated in the figures) that are arranged between the particle source 11 and the objective lens 3, or between the acceleration electrode 12 and the first multipole field generator 18. Typically, condenser lenses can be used to change the probe current or to adapt the illumination angle of the charged particle beam 3.

The particle beam system 100 further comprises a vacuum chamber 20. The vacuum chamber 20 has a chamber wall 21 defining the vacuum chamber 20. The vacuum chamber 20 is connected to the beam column 10. A vacuum can be generated inside the vacuum chamber 20. The beam 3 can enter the vacuum chamber 20 through an opening 22 encompassed by the objective lens 13.

The particle beam system 100 further comprises a sample stage 4 configured to hold the sample 2. The sample stage 4 can be configured to displace the sample 2 in one or more directions. The sample stage 4 can be configured to rotate the sample 2 about one or more axes of rotation. For example, the sample stage 4 can be configured to rotate the sample 2 about two or three axes of rotation. For example, the axes of rotation can be orthogonal to each other. The sample stage 4 is located inside the vacuum chamber 20.

The particle beam system 100 further comprises a controller 30 configured to control all or some of components of the particle beam system 100. For example, the controller 30 can be configured to control the beam column 10 via a signal connection 15 and the sample stage 4 via a signal connection 5. Specifically, the controller 30 can control the particle source 11, the acceleration electrode 12 (e.g., by controlling an electric potential applied to the acceleration electrode 12), the objective lens 13 (e.g., by controlling electric potential(s) and/or electric current(s) applied to the objective lens 13) and the beam deflection system 14 (e.g., by controlling electric potential(s) and/or electric current(s) applied to the beam deflection system 14).

The particle beam system 100 further comprises a data memory 31 configured to store data. The controller 30 can read data from the data memory 31 and write data into the data memory 31.

The particle beam system 100 further comprises an output device 32 configured to output information. For example, the output device 32 can be a display device for displaying information provided by the controller 30.

The particle beam system 100 further comprises an input device 33 for providing instructions to the controller 30. The input device 33 can comprise a mouse, a keyboard and the like, for example. The input device 33 can comprise a data interface for communication with another communication device.

The particle beam system 100 further comprises a detection system 40 configured to detect interaction products 41 emerging from the sample 2 due to an interaction of the beam 3 with the sample 2. For example, the detection system 40 can comprise at least one of a detector for detecting charged particles, such as backscattered ions, backscattered electrons, or secondary electrons, and a detector for detecting radiation such as light and x-rays. The detection system 40 is further configured to generate a detection signal based on the detected interaction products, to output the detection signal to the controller 30 via a signal connection 42, and to be adjusted by the controller 30 via the signal connection 42.

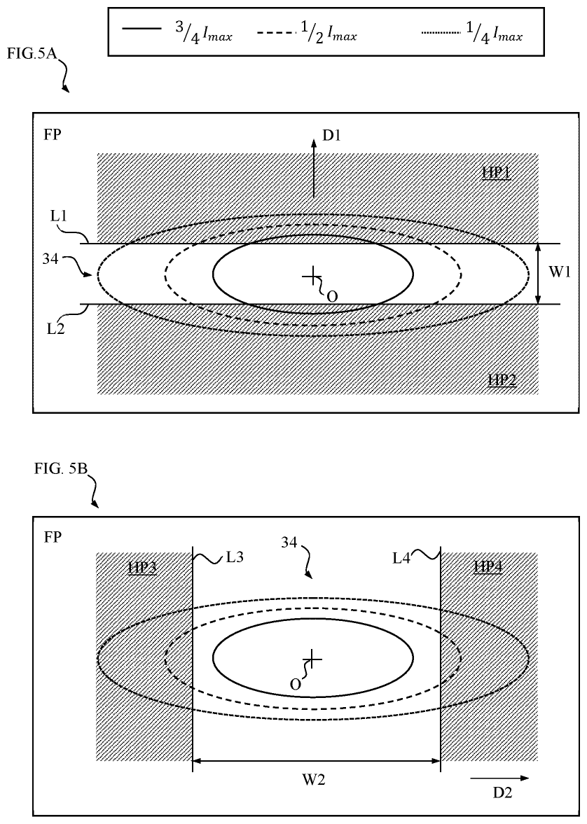

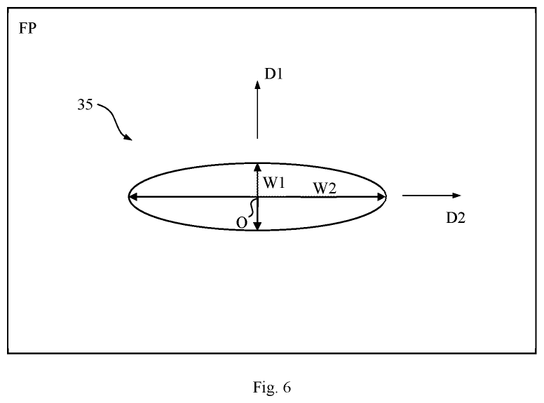

With reference to FIGS. 3 and 4, the function of the first multipole field generated by the first multipole field generator 18 is described below. FIG. 3 shows a schematic illustration of a trajectory of a fundamental ray 6 in a first plane defined by a first direction and a z-axis. FIG. 4 shows a schematic illustration of the trajectory of the fundamental ray 6 in a second plane defined by a second direction and the z-axis. The z-axis is chosen to correspond to the optical axis OA of the objective lens 13. The first direction and the second direction are specific directions defined in dependence of the beam profile of the beam 3 in the focal plane FP. The first direction is perpendicular to the z-axis. The second direction is perpendicular to the z-axis. The first direction and the second direction rotate about the z-axis in accordance with any Larmor precession present. That is, when observed from a stationary coordinate system, the first direction and the second direction rotate about the z-axis in dependence of the z-coordinate. Consequently, when observed from a stationary coordinate system, the first plane would be considered not a flat plane but helical; and the second plane would be considered not a flat plane but helical. In contrast, in a rotating coordinate system rotating about the z-axis with the Larmor precession, the first plane would be considered a flat plane; and the second plane would be considered a flat plane. FIGS. 3 and 4 show the first plane and the second plane in this rotating coordinate system, respectively. A particular definition of the first direction and the second direction is described with reference to FIGS. 5A and 5B.

In the example of FIGS. 3 and 4, the first direction is assumed to correspond to an x-axis; and the second direction is assumed to correspond to a y-axis. However, this selection is chosen for the purpose of explanation. The x-axis is perpendicular to the z-axis. The y-axis is perpendicular to both the x-axis and the z-axis. The first plane corresponds to the xz-plane; and the second plane corresponds to the yz-plane. The first plane (xz-plane) is perpendicular to the focal plane FP. The second plane (yz-plane) is perpendicular to the focal plane FP. Planes are perpendicular to each other if their respective normals (normal vectors) are perpendicular to each other.

The fundamental ray 6 passes through a circular aperture 16 of an aperture stop 17. The aperture stop 17 blocks a portion of the beam 3 and transmits another portion of the beam 3 through the aperture 16. The aperture stop 17 can be an additional component of the beam column 10 or can be functionally embodied by one of the other components of the beam column 10, such as the acceleration electrode 12, for example.

The objective lens 13 focuses the fundamental ray 6 having a predetermined kinetic energy En into the focal plane FP where the sample 2 is located. The trajectory of the fundamental ray 6 having the predetermined kinetic energy En is illustrated as a solid line. However, generally, the objective lens 13 causes chromatic aberration, i.e., the focusing differs for charged particles having different kinetic energies.

### Effect of First Multipole Field, Energy-Dispersive Focusing/Defocusing

In order to compensate the chromatic aberration of the objective lens 13 in the first direction (i.e., in the first plane), the first multipole field generated by the first multipole field generator 18 provides an energy-dispersive focusing/defocusing. That is, the first multipole field generator 18 is configured and operated so that the chromatic aberration of the focusing by the objective lens 13 in the first direction (x-axis) is reduced and that the chromatic aberration of the focusing by the objective lens 13 in the second direction (y-axis) is increased.

For example, as illustrated in FIG. 3, charged particles having the predetermined kinetic energy En (illustrated by a solid line), charged particles having a kinetic energy El (illustrated by a dashed line) less than the predetermined kinetic energy En and charged particles having a kinetic energy Eh (illustrated by a dotted line) greater than the predetermined kinetic energy En are focused by the first multipole field in the first direction (x-axis) with different powers so that an energy-dispersive focusing of the objective lens 13 (i.e., chromatic aberration) is compensated. Further, as illustrated in FIG. 4, charged particles having the predetermined kinetic energy En (illustrated by a solid line), charged particles having the kinetic energy El (illustrated by a dashed line) less than the predetermined kinetic energy En and charged particles having the kinetic energy Eh (illustrated by a dotted line) greater than the predetermined kinetic energy En are focused by the first multipole field in the second direction (y-axis) with different powers so that the energy-dispersive focusing of the objective lens 13 (i.e., chromatic aberration) is not compensated but even increased.

Note that the expression “focusing” represents both of converging focusing, i.e., focusing with a positive optical power, and diverging focusing, i.e., focusing with a negative optical power, also referred to as defocusing. Accordingly, converging focusing is focusing with a power greater than that of diverging focusing; and diverging focusing (or defocusing) is focusing with a power less than that of converging focusing.

Referring to FIG. 3, the first multipole field generator 18 is operated to focus the charged particles having the kinetic energy El (illustrated by a dashed line) in the first plane (xz-plane) with a power which is smaller than a power with which the first multipole field generator 18 focuses the charged particles having the kinetic energy En (illustrated by a solid line) in the first plane (xz-plane). In the example of FIG. 3, the first multipole field generator 18 is operated to defocus (i.e., focus with negative power) the charged particles having the kinetic energy El (illustrated by a dashed line) in the first plane (xz-plane), whereas the charged particles having the kinetic energy En (illustrated by a solid line) are not focused (i.e., focused with power of 0) in the first plane (xz-plane). Further, the first multipole field generator 18 is operated to focus the charged particles having the kinetic energy Eh (illustrated by a dotted line) in the first plane (xz-plane) with a power which is greater than the power with which the first multipole field generator 18 focuses the charged particles having the kinetic energy En (illustrated by a solid line) in the first plane (xz-plane). In the example of FIG. 3, the first multipole field generator 18 is operated to focus (i.e., focus with positive power) the charged particles having the kinetic energy Eh (illustrated by a dotted line) in the first plane (xz-plane), whereas the charged particles having the kinetic energy En (illustrated by a solid line) are not focused (i.e., focused with power of 0) in the first plane (xz-plane).

Referring to FIG. 4, the first multipole field generator 18 is operated to focus the charged particles having the kinetic energy Eh (illustrated by a dotted line) in the second plane (yz-plane) with a power which is smaller than a power with which the first multipole field generator 18 focuses the charged particles having the kinetic energy En (illustrated by a solid line) in the second plane (yz-plane). In the example of FIG. 4, the first multipole field generator 18 is operated to defocus (i.e., focus with negative power) the charged particles having the kinetic energy Eh (illustrated by a dotted line) in the second plane (yz-plane), whereas the charged particles having the kinetic energy En (illustrated by a solid line) are not focused (i.e., focused with power of 0) in the second plane (yz-plane). Further, the first multipole field generator 18 is operated to focus the charged particles having the kinetic energy El (illustrated by a dashed line) in the second plane (yz-plane) with a power which is greater than the power with which the first multipole field generator 18 focuses the charged particles having the kinetic energy En (illustrated by a solid line) in the second plane (yz-plane). In the example of FIG. 4, the first multipole field generator 18 is operated to focus (i.e., focus with positive power) the charged particles having the kinetic energy El (illustrated by a dashed line) in the second plane (yz-plane), whereas the charged particles having the kinetic energy En (illustrated by a solid line) are not focused (i.e., focused with power of 0) in the second plane (yz-plane).

Note that the effect on the trajectories of the charged particles achieved by the first multipole field generator 18 is illustrated in an exaggerated fashion for the purpose of illustration. That is, the amount of change in propagation direction of charged particles effected by the first multipole field generator 18 is exaggerated in comparison to the real effect.

The focusing by the objective lens 13 is achieved by a magnetic and/or electric field. A focusing power of the focusing by the objective lens 13 increases with decreasing kinetic energy of the charged particles. Consequently, in the first plane (xz-plane) illustrated in FIG. 3, due to their decreased kinetic energy, the charged particles of the fundamental ray 6 having the kinetic energy El exhibit a stronger focusing by the objective lens 13 than the charged particles of the fundamental ray 6 having the predetermined kinetic energy En; and the charged particles of the fundamental ray 6 having the predetermined kinetic energy En exhibit a stronger focusing by the objective lens 13 than the charged particles of the fundamental ray 6 having the kinetic energy Eh. Consequently, when appropriately excited, the first multipole field reduces the chromatic aberration of the focusing by the objective lens 13 in the first direction (x-axis). FIG. 3 illustrates an example in which the first multipole field is excited so as to completely compensate the chromatic aberration in the first direction.

However, as illustrated in FIG. 4, the energy-dispersive focusing/defocusing of the first multipole field introduces additional chromatic aberration on top of the chromatic aberration of the focusing by the objective lens 13 in the second direction (y-axis). For example, the first multipole field focusses the charged particles of the fundamental ray 6 having the kinetic energy El (illustrated as a dashed line) greater than the charged particles of the fundamental ray 6 having the predetermined kinetic energy En in the second direction (y-axis). Further, the first multipole field focusses the charged particles of the fundamental ray 6 having the kinetic energy Eh (illustrated as a dotted line) less (i.e., the first multipole field defocusses the charged particles of the fundamental ray 6 having the kinetic energy Eh greater) than the charged particles of the fundamental ray 6 having the predetermined kinetic energy En in the second direction (y-axis).

### Effect in Focal Plane FP, Beam Profile

Referring to FIGS. 5 and 6, the effect of the first multipole field on the beam 3 is further described. FIGS. 5A and 5B show a schematic illustration of a beam profile 34 of the beam 3 in the focal plane FP. The beam profile 34 of the beam 3 in the focal plane FP is schematically illustrated by three isolines and a point O, which are described below. The point O represents a center of an intensity distribution of the beam 3 in the focal plane FP. For example, the center of the intensity distribution of the beam 3 in the focal plane FP can be determined using the formula

$$\vec{O} = \frac{1}{{I}_{total}} {\int }_{F P} \vec{r} \cdot I ( \vec{r} ) d A ,$$

wherein \vec{O} represents the center of the intensity distribution of the beam 3 in the focal plane FP, F represents a spatial vector in the focal plane FP, l(\vec{r}) represents the intensity distribution in dependence of the spatial vector \vec{r}, Iₜₒₜₐₗ represents a total intensity of the beam 3 in the focal plane FP. The Integration is performed over the entire focal plane FP. For example, Iₜₒₜₐₗ can be determined using the formula

$${I}_{totat} = {\int }_{F P} I ( \vec{r} ) d A .$$

Each isoline represents locations in the focal plane FP at which the local intensity of the beam 3 amounts to a same value. In the illustrated example, the isolines have an elliptic shape and are centered on a center O of the intensity distribution of the beam 3 in the focal plane FP. For example, the isoline closest to the center O is illustrated by a solid line and represents locations in the focal plane FP at which the local intensity of the beam 3 amounts to ¾ Iₘₐₓ, wherein Iₘₐₓ represents the maximum value of the intensity distribution of the beam 3 in the focal plane FP. Further, the isoline second-closest to the center O is illustrated by a dashed line and represents locations in the focal plane FP at which the local intensity of the beam 3 amounts to ½ Iₘₐₓ. Finally, the isoline furthest from the center O is illustrated by a dotted line and represents locations in the focal plane FP at which the local intensity of the beam 3 amounts to ¼ Iₘₐₓ. At the center O, the local intensity of the beam 3 amounts to Iₘₐₓ.

Hereinafter, the beam profile 34 of the beam 3 in the focal plane FP will be characterized by a direction-specific interaction length defined as follows: An interaction length specific to a direction in the focal plane indicates a distance, measured along the specific direction, between a first straight line perpendicular to the specific direction and a second straight line perpendicular to the specific direction, wherein the first straight line defines a first half-plane, wherein the first half-plane is located in the focal plane and contains 25% of the total intensity of the beam in the focal plane (i.e., 25% of Iₜₒₜₐₗ), wherein the second straight line defines a second half-plane, wherein the second half-plane is located in the focal plane and contains 25% of the total intensity of the beam in the focal plane (i.e., 25% of Iₜₒₜₐₗ) and does not overlap the first half-plane.

Accordingly, a strip in the focal plane, including an area between the first straight line and the second straight line, contains 50% of the total intensity Iₜₒₜₐₗ of the beam 3 in the focal plane FP. The first half-plane and the second half-plane together contain the other 50% of the total intensity Iₜₒₜₐₗ of the beam 3 in the focal plane FP.

The above definition of the interaction length is applied to the beam profile 34 of the beam 3 illustrated in FIG. 5A for a first direction D1 in the focal plane FP, resulting in a first interaction length W1 for the first direction D1: A first half-plane HP1 is located in the focal plane FP and is defined by (i.e., is limited by) a first straight line L1 in the focal plane FP. The first straight line L1 is perpendicular to the first direction D1. The first half-plane HP1 contains 25% of the total intensity of the beam in the focal plane FP. A second half-plane HP2 is also located in the focal plane FP and is defined by (i.e., is limited by) a second straight line L2 in the focal plane FP. The second straight line L2 is also perpendicular to the first direction D1. The second half-plane HP2 also contains 25% of the total intensity of the beam in the focal plane FP. The first half-plane HP1 and the second half-plane HP2 do not overlap each other. The first interaction length W1 is the distance, measured along the first direction D1, between the first line L1 and the second line L2.

In FIGS. 5A and 5B, the first half-plane HP1 is illustrated by a hatched area. Please note that the first half-plane HP1 extends beyond the illustrated hatched area along the positive first direction D1 and directions perpendicular to the first direction D1. In FIGS. 5A and 5B, the second half-plane HP2 is also illustrated by a hatched area. Please note that the second half-plane HP2 extends beyond the illustrated hatched area along the negative first direction D1 and directions perpendicular to the first direction D1.

The above definition of the interaction length is applied to the beam profile 34 of the beam 3 illustrated in FIG. 5B for a second direction D2 in the focal plane FP, which is different from the first direction D1, resulting in a second interaction length W2 for the second direction D2: A third half-plane HP3 is located in the focal plane FP and is defined by (i.e., is limited by) a third straight line L3 in the focal plane FP. The third straight line L3 is perpendicular to the second direction D2. The third half-plane HP3 contains 25% of the total intensity of the beam in the focal plane FP. A fourth half-plane HP4 is also located in the focal plane FP and is defined by (i.e., is limited by) a fourth straight line L4 in the focal plane FP. The fourth straight line L4 is also perpendicular to the second direction D2. The fourth half-plane HP4 also contains 25% of the total intensity of the beam in the focal plane FP. The third half-plane HP3 and the fourth half-plane HP4 do not overlap each other. The second interaction length W2 is the distance, measured along the second direction D2, between the third line L3 and the fourth line L4.

FIG. 6 shows a schematic illustration of an interaction profile 35 of the beam 3 having the beam profile 34 illustrated in FIGS. 5A and 5B. The interaction profile 35 represents the direction-specific interaction lengths for all directions of the focal plane FP. Each of the interaction lengths is indicated by two points which are arranged on a line oriented along the direction associated with the respective interaction length and are separated by a distance corresponding to the respective interaction length. Consequently, the interaction length W1 for the first direction D1 is illustrated as two points arranged along the direction D1 and separated by a distance W1. Similarly, the interaction length W2 for the second direction D2 is illustrated as two points arranged along the direction D2 and separated by a distance W2. For the beam profile 34 illustrated in FIGS. 5A and 5B, this results in an interaction profile 35 having an elliptic shape when the lines representing the interaction lengths are centered on a common center.

As illustrated in FIGS. 5 and 6, the interaction length W1 for the first direction D1 is shorter than the interaction length W2 for the second direction D2. Consequently, when using the beam 3 as a scanning microscope probe, in a resulting image, the maximum resolution in the first direction D1 is higher than the maximum resolution in the second direction D2. This means that the resolution in the first direction D1 is better than the resolution in the second direction D2 when the beam 3 having the illustrated intensity distribution is used for recording an image. Specifically, the beam profile 34 illustrated in FIGS. 5A and 5B, resulting in the interaction profile 35 illustrated in FIG. 6, is particularly suited for recording images of a sample having straight microstructures (such as straight edges). For example, when the beam 3 is orientated so that the first direction D1 is perpendicular to the straight microstructures (i.e., the first line L1 is parallel to the straight microstructures), the obtained resolution along the first direction D1 will be exceptionally good. However, simultaneously, the obtained resolution along the second direction D2 will be worse.

Furthermore, a conventional non-corrected particle beam system provides a uniform interaction length WN for all directions in the focal plane, i.e., the beam of the conventional non-corrected particle beam system provides the same interaction length for every direction in the focal plane. Compared to such a conventional non-corrected particle beam system, the interaction length W1 for the first direction D1 according to the present embodiment is also shorter than the interaction length WN of the conventional non-corrected particle beam system.

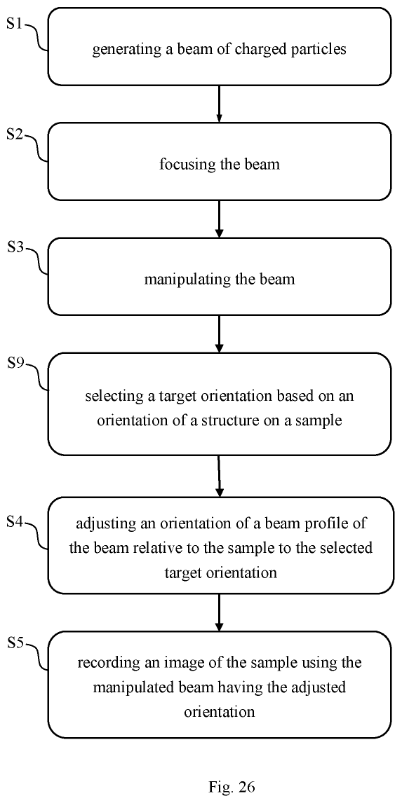

This improved resolution along the first direction D1 can be beneficial in multiple applications, examples of which are described further below with reference to FIGS. 25 and 26.

A ratio of the first interaction length W1 to the second interaction length W2 amounts to at most 1:1.2. Optionally, the ratio of the first interaction length W1 to the second interaction length W2 amounts to at most 1:1.3 or at most 1:2.0 or at most 1:3.0. In the example illustrated in FIG. 6, the ratio of the first interaction length W1 to the second interaction length W2 amounts to approximately 1:3. Within specific limits, when using the beam 3 having the beam profile illustrated in FIGS. 5A and 5B as a scanning microscope probe, the resolution in the first direction D1 improves relative to the resolution in the second direction D2 with decreasing values of the ratio.

The primary objective of the present disclosure is to reduce the absolute value of first interaction length W1, thereby improving the resolution in the direction D1. The secondary objective of the present disclosure is to achieve the primary objective while maximizing the value of the ratio W1 to W2, thereby avoiding an unnecessarily long second interaction length W2.

### Implementation of the First Multipole Field Generator 18

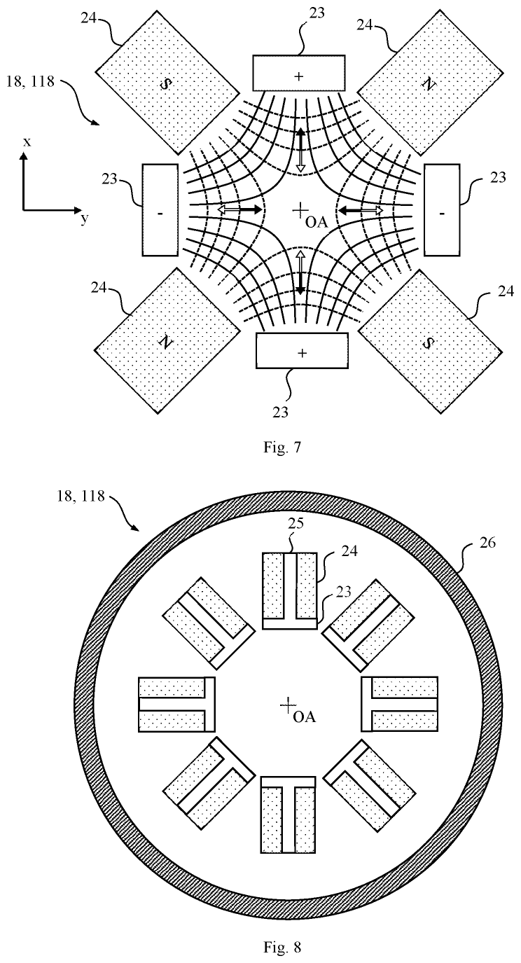

Exemplary implementations of the first multipole field generator 18 are described with reference to FIGS. 7 and 8. FIGS. 7 and 8 show a cross-section of the first multipole field generator 18 in a plane coplanar to the focal plane FP, i.e., in a plane perpendicular to the optical axis OA of the objective lens 13.

According to FIG. 7, the first multipole field generator 18 comprises four electrodes 23 for providing electric poles and four coils 24 for providing magnetic poles. The electrodes 23 and the coils 24 are arranged about a common center located at the optical axis OA of the objective lens 13. In circumferential direction about the common center, the electrodes 23 and the coils 24 are disposed alternately. By appropriate application of voltages and currents to the electrodes 23 and the coils 24, respectively, various types of electric and magnetic multipole fields can be generated. For example, the configuration allows to generate electric and magnetic dipole fields and quadrupole fields of selectable strength. For further reference, the electrodes 23 generate a first electric multipole field; and the coils 24 generate a first magnetic multipole field. The first electric multipole field and the first magnetic multipole field are superimposed on each other.

According to a specific mode of operation illustrated in FIG. 7, poles facing each other across the optical axis OA of the objective lens 13 are of the same type, i.e., two positive electric poles denoted “+” face each other across the optical axis OA of the objective lens 13, two negative electric poles denoted “−” face each other across the optical axis OA of the objective lens 13, two magnetic north poles denoted “N” face each other across the optical axis OA of the objective lens 13, and two magnetic south poles denoted “S” face each other across the optical axis OA of the objective lens 13. Accordingly, the first electric multipole field is a quadrupole field; and the first magnetic multipole field is a quadrupole field. In general, the first electric multipole field has a four-pole component, and the first magnetic multipole field has a four-pole component.

Solid lines in FIG. 7 schematically indicate different field lines of the first electric multipole field. Solid arrows in FIG. 7 indicate forces generated by the first electric multipole field on a charged particle, in the illustrated example an electron, (of the beam 3) at the respective locations. The magnitude of the force generated by the first electric multipole field increases (linearly) with increasing distance from the optical axis OA. Dashed lines in FIG. 7 schematically indicate different flux lines of the first magnetic multipole field. Hollow arrows in FIG. 7 indicate forces generated by the first magnetic multipole field on a charged particle, in the illustrated example an electron, (of the beam 3) at the respective locations. The magnitude of the force generated by the first magnetic multipole field increases (linearly) with increasing distance from the optical axis OA.

While the force generated by the first electric multipole field does not depend on the velocity (kinetic energy) of the charged particles, the force generated by the first magnetic multipole field does depend on the kinetic energy (does depend linearly on the velocity) of the charged particles. Consequently, the net force acting on a charged particle depends on the kinetic energy (does depend linearly on the velocity) of the charged particle. Further, the net force acting on a charged particle depends (linearly) on the distance of the charged particle from the optical axis OA.

For example, the first electric multipole field and the first magnetic multipole field can be generated so that charged particles of the beam 3 having the predetermined energy En are not influenced, i.e., the force generated by the first electric multipole field integrated along propagation paths of the charged particles of the beam 3 having the predetermined energy En and the force generated by the first magnetic multipole field integrated along the propagation paths practically cancel each other for charged particles having the predetermined energy En. In contrast to that, charged particles having a kinetic energy Eh greater than the predetermined energy En exhibit a net force along the direction of the hollow arrow representing the force generated by the first magnetic multipole field; and charged particles having a kinetic energy El less than the predetermined energy En exhibit a net force along the direction of the solid arrow representing the force generated by the first electric multipole field. Consequently, charged particles having a kinetic energy Eh greater than the predetermined energy En are focused in the first direction (x-axis) and are defocused in the second direction (y-axis); and charged particles having a kinetic energy El less than the predetermined energy En are defocused in the first direction (x-axis) and are focused in the second direction (y-axis).

While the first multipole field generator 18 described with reference to FIG. 7 comprises four electrodes 23 and four coils 24, other implementations of the first multipole field generator 18 can comprise more than four electrodes and more than four coils.

As illustrated in FIG. 8, the first multipole field generator 18 can comprise eight electrodes 23 for providing electric poles and eight coils 24 for providing magnetic poles. The electrodes 23 and the coils 24 are arranged about a common center located at the optical axis OA of the objective lens 13. By appropriate application of voltages and currents to the electrodes 23 and the coils 24, respectively, various types of electric and magnetic multipole fields can be generated. For example, the configuration allows to generate electric and magnetic dipole fields and quadrupole fields of selectable strength and selectable orientation as well as electric and magnetic octupole fields of selectable strength.

The coils 24 can be wound around a non-magnetic material. Alternatively, the coils 24 can be wound around magnetic pole pieces 25 guiding the magnetic field generated by the coils 24 and increasing the magnetic field strength at the optical axis OA of the objective lens 13. The pole pieces 25 can be electrically isolated by a high-voltage isolation or by (vacuum) gaps. The magnetic pole pieces 25 can also serve as the electrodes 23. Some of the electrodes 23 can be supplied by the same voltage supply, thereby reducing the amount of independent voltage sources and increasing stability of the generated field at the cost of reduced flexibility. For example, electrodes arranged opposite to each other across the optical axis OA can be supplied by a same voltage source. Some of the coils 24 can be connected to each other, for example connected in series, thereby reducing the amount of independent current sources and increasing stability of the generated field at the cost of reduced flexibility. For example, coils arranged opposite to each other across the optical axis OA can be supplied by a same current source. An additional yoke 26 surrounding the coils 24 on the radial outside can be provided for supporting the magnetic flux (“closing” the magnetic flux path) and further increasing the magnetic field strength at the optical axis OA of the objective lens 13.

By appropriate application of voltages and currents to the electrodes 23 and the coils 24 of the first multipole field generator 18 illustrated in FIG. 8, the first multipole field generator 18 can generate the first electric multipole field as a quadrupole field and the first magnetic multipole field as a quadrupole field and can selectively rotate both about the optical axis OA, thereby adjusting the orientation of the first multipole field (i.e., rotating the first multipole field). Accordingly, an orientation of the beam profile in the focal plane FP relative to the sample 3 can be adjusted to a target orientation by rotating the first multipole field.

While FIG. 7 describes the first multipole field generator 18 as to comprise four electrodes and four coils and FIG. 8 describes the first multipole field generator 18 as to comprise eight electrodes and eight coils, other implementations of the first multipole field generator 18 can comprise even more electrodes and coils. For example, the first multipole field generator 18 can comprise twelve or sixteen electrodes and coils. Consequently, rotatable multipole fields of higher order, such as a rotatable electric octupole field and a rotatable magnetic octupole field, can be generated for higher order manipulations of the beam 3.

In order to reduce a contribution to focusing, to spherical aberration Cs, and to four-fold astigmatism C₄ at a fringing field region (i.e., where charged particles enter or leave the multipole field), and in order to increase the multipole field strength at a certain excitation, the first multipole field generator 18 can have a lengthy configuration. For example, an aspect ratio of the first multipole field generator 18, defined as a ratio of (1.) the length of the first multipole field generator 18 along the optical axis OA to (2.) the bore diameter of the first multipole field generator 18 perpendicular to the optical axis OA can amount to values ranging from 5 to 100, for example.

As can be understood from FIGS. 2 to 4, except for the first multipole field generated by the first multipole field generator 18, no other electric or magnetic fields are provided for correcting the chromatic aberration of the focusing by the objective lens 13 in a direction different from the first direction (x-axis). This simplifies the structure of the particle beam system 100 and reduces its costs.

### Second Embodiment: Chromatic Aberration Correction in One Direction & Non-Circular Aperture Stop

As described above with reference to FIGS. 3 and 4, the aperture stop 17 has a circular aperture 16. Consequently, the beam 3 has a circular beam shape in a plane OL which is coplanar to the focal plane FP and located at the position of the objective lens 13. Further, the first multipole field generator 18 does not focus/defocus the charged particles having the predetermined kinetic energy En of the beam 3 or provides a uniform focusing/defocusing along the first direction (x-axis) and the second direction (y-axis). Consequently, as illustrated in FIGS. 3 and 4, a maximum illumination angle ϑₓ of the beam 3 in the first plane (xz-plane) and a maximum illumination angle ϑ_{y} of the beam 3 in the second plane (yz-plane) for charged particles having the predetermined kinetic energy En are the same.

The maximum illumination angle of the beam 3 in a given plane is defined as a largest one of all landing angles of the charged particles having the predetermined kinetic energy En of the beam 3 in the given plane, wherein the landing angle of a charged particle is defined as an angle between the trajectory of the charged particle at the focal plane FP and a normal vector of the focal plane FP.

However, the inventors understood that adjusting the maximum illumination angle ϑₓ of the beam 3 in the first plane (xz-plane) to a first maximum illumination angle value and adjusting the maximum illumination angle ϑ_{y} of the beam 3 in the second plane (yz-plane) to a second maximum illumination angle value different from the first maximum illumination angle value can further reduce the first interaction length W1 for the first direction D1. This effect is utilized in the second embodiment described below. Further explanations of the effect are provided below with reference to the particle beam system 500 and the optimization routines and procedures.

In order to utilize this understanding, in addition to the features of the particle beam system 100 according to the first embodiment, a particle beam system 200 according to the second embodiment further comprises a mechanism for independently manipulating the maximum illumination angle ϑₓ of the beam 3 in the first plane (xz-plane) and the maximum illumination angle ϑ_{y} of the beam 3 in the second plane (yz-plane).

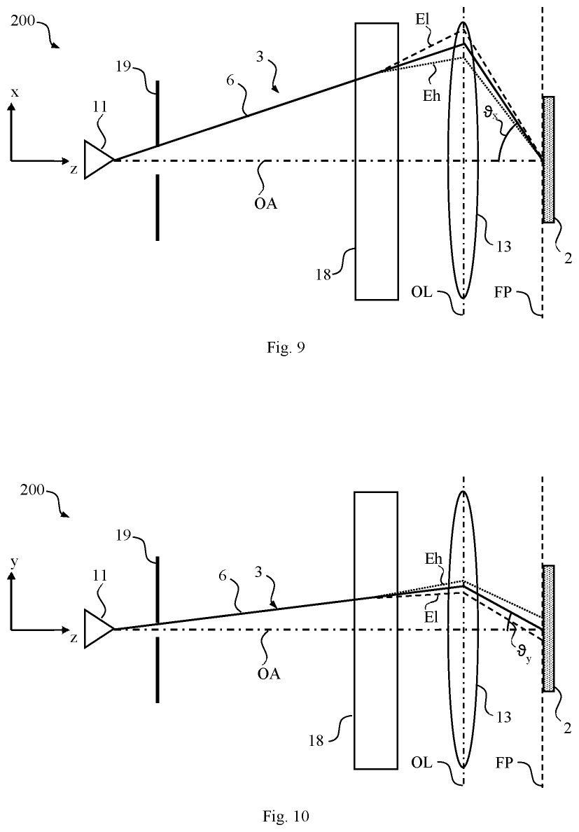

The second embodiment will be described with reference to FIGS. 9 and 10. Similar to FIGS. 3 and 4, FIGS. 9 and 10 show the first and second plane in a rotating coordinate system rotating with the Larmor precession, respectively. That is, although illustrated in a flat plane, the x-axis and the y-axis rotate about the z-axis in dependence of the z-coordinate in accordance with the Larmor precession.

The particle beam system 200 according to the second embodiment is obtained by replacing the aperture stop 17 having the circular aperture 16 of the particle beam system 100 according to the first embodiment by an aperture stop 19 having a non-circular aperture such as an elliptical aperture. In the example illustrated in FIGS. 9 and 10, the aperture of the aperture stop 19 is wider along the first direction (x-axis, FIG. 9) than along the second direction (y-axis, FIG. 10). Consequently, a maximum angle between the optical axis OA of the objective lens 13 and the trajectory of the fundamental ray 6 of the beam 3 behind the aperture stop 19 in the first plane (xz-plane) is (much) greater than a maximum angle between the optical axis OA of the objective lens 13 and the trajectory of the fundamental ray 6 of the beam 3 behind the aperture stop 19 in the second plane (yz-plane). The aperture stop 19 having the non-circular aperture generates a non-circular beam shape of the beam 3 in the plane OL and causes the first and second maximum illumination angle values to be different. In this context, a beam has a non-circular beam shape if a beam contour corresponding to a limiting aperture stop has a non-circular shape. Herein, the expressions beam contour and beam shape are used synonymously. Herein, the above effect is referred to as direction-dependent widening of the beam 3 which means that widening of the beam 3 in the first plane (xz-plane) is different from widening of the beam 3 in the second plane (yz-plane).

Similar to the first embodiment, the first multipole field generator 18 provides energy-dispersive focusing/defocusing. Similar to the first embodiment, the first multipole field generator 18 is configured and operated so that the chromatic aberration of the focusing by the objective lens 13 in the first direction (x-axis) is reduced and that the chromatic aberration of the focusing by the objective lens 13 in the second direction (y-axis) is increased.

### Effect of Beam Widening in Plane OL

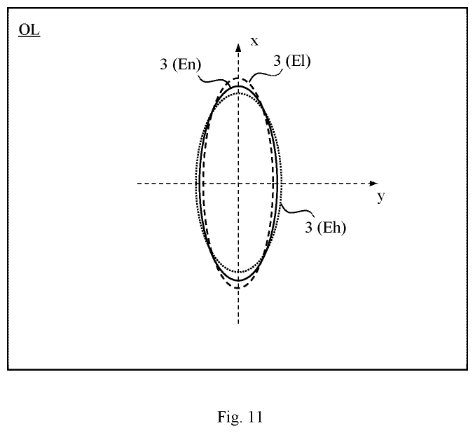

FIG. 11 shows a schematic illustration of a plurality of energy-specific beam contour (i.e., a plurality of energy-specific beam contours) of the beam 3 in the plane OL in accordance with the trajectories illustrated in FIGS. 9 and 10. In this context, an energy-specific beam contour is a beam contour for a beam has only particles having the specific (kinetic) energy.

For example, FIG. 11 shows an energy-specific beam contour of the charged particles having the predetermined kinetic energy En (illustrated by a solid line), an energy-specific beam contour of the charged particles having the kinetic energy El (illustrated by a dashed line) less than the predetermined kinetic energy En, and an energy-specific beam contour of the charged particles having the kinetic energy Eh (illustrated by a dotted line) greater than the predetermined kinetic energy En. Although not drawn to scale, FIG. 11 yet illustrates that the influence of the energy-dispersive focusing/defocusing of the first multipole field generator 18 on the energy-specific beam contours is much smaller than the influence of the direction-dependent widening by the aperture stop 19 having the non-circular aperture. In other words, the effect of the direction-dependent widening by the aperture stop 19 having the non-circular aperture is much greater than the effect by the energy-dispersive focusing of the first multipole field generator 18. However, in order to illustrate the principle of both effects, the illustrated deflection caused by the energy-dispersive focusing of the first multipole field generator 18 is exaggerated.

In the illustrated example, the beam 3 has elliptical energy-specific beam contours with a long axis along the first direction (x-axis) and a short axis along the second direction (y-axis). An aspect ratio of an (energy-specific) beam contour in the plane OL is defined as a ratio of the diameter of the beam contour in the first direction (x-axis) to the diameter of the beam contour in the second direction (y-axis). As illustrated in FIG. 9, a large diameter of the beam 3 in the plane OL along the first direction (x-axis) causes a large maximum illumination angle ϑₓ in the first plane (xz-plane). As illustrated in FIG. 10, a small diameter of the beam 3 in the plane OL along the second direction (y-axis) causes a small maximum illumination angle ϑ_{y} in the second plane (yz-plane).

### Effect in Focal Plane FP, Beam Profile

Similar to the above embodiment, the particle beam system 200 according to the second embodiment generates a beam profile having a non-circular interaction profile 35 in the focal plane FP as illustrated in FIG. 6, thus providing the same benefits. Also, the interaction length W1 in the first direction D1 obtained in the second embodiment is strongly reduced in comparison to the interaction length WN of a conventional particle beam system.

### Adjusting the Orientation of the Beam Profile

The aperture stop 19 having the non-circular aperture can be rotatable about the optical axis OA of the objective lens 13, for example, by a controllable actuator. Accordingly, by rotating the aperture stop 19 and the first multipole field generated by the first multipole field generator 18 about the optical axis OA of the objective lens 13, the orientation of the beam profile of the beam 3 in the focal plane FP relative to the sample 2 can be adjusted. The first multipole field can be rotated by rotating the multipole field generator 18 and/or by appropriate excitation of the individual electrodes/coils of the multipole field generator 18.

### Third Embodiment: Chromatic Aberration Correction in One Direction & Beam Widening by Separate Field Generators

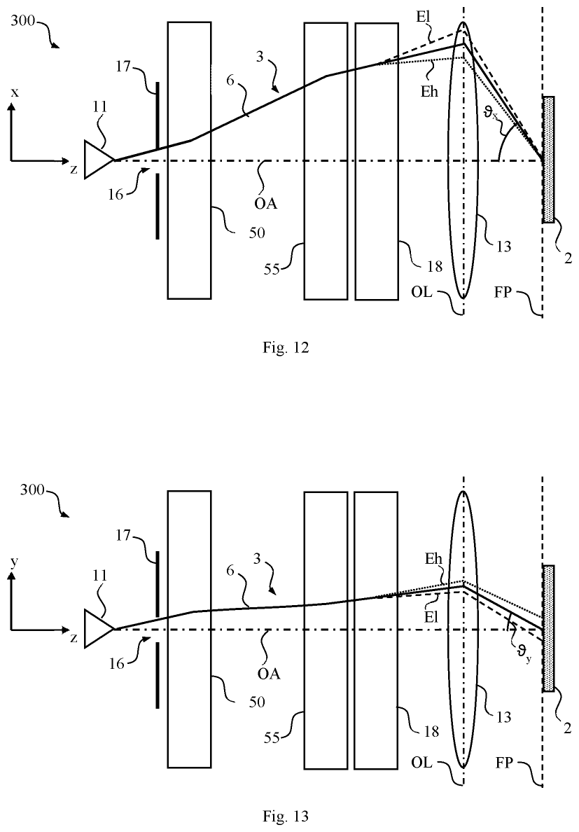

A particle beam system 300 according to a third embodiment is described below with reference to FIGS. 12 and 13. The particle beam system 300 differs from the particle beam system 100 according to the first embodiment by further comprising a mechanism for independently manipulating the maximum illumination angle ϑₓ of the beam 3 in the first plane (xz-plane) and the maximum illumination angle ϑ_{y} of the beam 3 in the second plane (yz-plane). The particle beam system 300 differs from the particle beam system 200 according to the second embodiment by comprising a different mechanism for independently manipulating the maximum illumination angle ϑₓ of the beam 3 in the first plane (xz-plane) and the maximum illumination angle ϑ_{y} of the beam 3 in the second plane (yz-plane).

In the third embodiment, the mechanism for independently manipulating the maximum illumination angle ϑₓ of the beam 3 in the first plane (xz-plane) and the maximum illumination angle ϑ_{y} of the beam 3 in the second plane (yz-plane) is achieved by a two-stage direction-dependent focusing which is implemented by a second multipole field generator 50 configured to generate a second multipole field (first stage) and a third multipole field generator 55 configured to generate a third multipole field (second stage). The second multipole field generator 50 and the third multipole field generator 55 are disposed downstream of the aperture stop 17 having the circular aperture (similar to the first embodiment) and upstream of the objective lens 13, for example upstream of the first multipole field generator 18. In the illustrated example, the second multipole field generator 50 is disposed downstream of the aperture stop 17 and upstream of the third multipole field generator 55. However, other arrangements are possible. For example, the arrangement of the first multipole field generator 18, the second multipole field generator 50 and the third multipole field generator 55 can be different.

Similar to FIGS. 3 and 4, FIGS. 12 and 13 show the first and second plane in a rotating coordinate system rotating with the Larmor precession. That is, although illustrated in a flat plane, the x-axis and the y-axis rotate about the z-axis in dependence of the z-coordinate in accordance with the Larmor precession.

FIG. 12 shows trajectories of charged particles of the beam 3 in the first plane (xz-plane) including the fundamental ray 6. FIG. 13 shows the trajectories of the same charged particles of the beam 3 in the second plane (yz-plane) including the fundamental ray 6.

The second multipole field generator 50 is configured to generate the second multipole field so that the charged particles of the beam 3 are focused according to a selectable first focusing power in the first plane (xz-plane) and the charged particles of the beam 3 are focused according to a selectable second focusing power in the second plane (yz-plane), wherein the first focusing power is less than the second focusing power. For example, the second focusing power is selected to be equal to the negative first focusing power. Accordingly, upon propagation of the beam 3 between the second multipole field generator 50 and the third multipole field generator 55, the beam 3 widens along the first direction (x-axis) (much) more than it widens along the second direction (y-axis). The second multipole field comprises at least one of a second electric multipole field and a second magnetic multipole field. The second multipole field can provide an optical power of at least 2 diopters, such as at least 6 diopters, for example at least 10 diopters. Accordingly, the second multipole field is much stronger than a conventional stigmator field. However, the second multipole field is much weaker than the first electric or magnetic multipole field. According to an example, the second multipole field comprises a quadrupole field. According to an example, the second electric multipole field comprises an electric quadrupole field. According to an example, the second magnetic multipole field comprises a magnetic quadrupole field.

The third multipole field generator 55 is configured to generate the third multipole field so that the charged particles of the beam 3 are focused according to a selectable third focusing power in the first plane (xz-plane) and the charged particles of the beam 3 are focused according to a selectable fourth focusing power in the second plane (yz-plane), wherein the third focusing power is greater than the fourth focusing power. For example, the fourth focusing power is selected to be equal to the negative third focusing power. The third multipole field comprises at least one of a third electric multipole field and a third magnetic multipole field. The third multipole field can provide an optical power of at least 2 diopters, such as at least 6 diopters, for example at least 10 diopters. Accordingly, the third multipole field is much stronger than a conventional stigmator field. However, the third multipole field is much weaker than the first electric or magnetic multipole field. According to an example, the third multipole field comprises a quadrupole field. According to an example, the third electric multipole field comprises an electric quadrupole field. According to an example, the third magnetic multipole field comprises a magnetic quadrupole field.

The first to fourth focusing powers define the focusing for the charged particles having the predetermined kinetic energy En. The focusing powers are selected so that an astigmatic effect is avoided. That is, the focusing powers are selected so that, at the objective lens 13, the beam 3 appears to emerge from a single virtual source. In cooperation, the second multipole field generator 50 and the third multipole field generator 55 provide selectable direction-dependent widening of the beam 3. Due to the selectable direction-dependent widening of the beam 3 between the second multipole field generator 50 and the third multipole field generator 55, the maximum illumination angle ϑₓ and the maximum illumination angle ϑ_{y} can be manipulated independently. For example, as illustrated in the example, the maximum illumination angle ϑₓ can be made (much) greater than the maximum illumination angle ϑ_{y}.

Similar to the first and second embodiment, the first multipole field generator 18 provides energy-dispersive focusing/defocusing. Similar to the first and second embodiment, the first multipole field generator 18 is configured and operated so that the chromatic aberration of the focusing by the objective lens 13 in the first direction (x-axis) is reduced and that the chromatic aberration of the focusing by the objective lens 13 in the second direction (y-axis) is increased.

### Effect of Beam Widening in Plane OL

Similar to the second embodiment, the particle beam system 300 according to the third embodiment generates a beam 3 having a non-circular beam shape as illustrated in FIG. 11, thus providing the same benefits. In contrast to the second embodiment, the effect of the direction-dependent widening can be adapted easily by changing the strengths of the second and third multipole fields generated by the second multipole field generator 50 and the third multipole field generator 55, respectively.

In order to achieve a sufficient aspect ratio of the beam shape of the beam 3 in the objective lens 13, a distance between the second multipole field generator 50 and the third multipole field generator 55 along the optical axis OA of the objective lens 13 is sufficiently large. In some embodiments, aspect ratios of the beam shape of the beam 3 in the objective lens 13 provided by the mechanism for independently manipulating the maximum illumination angles range from about 2 to 5. Therefore, the distance between the second multipole field generator 50 and the third multipole field generator 55 is about 5 cm to 20 cm.

### Effect in Focal Plane FP, Beam Profile

Similar to the above embodiments, the particle beam system 300 according to the third embodiment generates a beam profile having a non-circular interaction profile 35 in the focal plane FP as illustrated in FIG. 6, thus providing the same benefits. Also, the interaction length W1 in the first direction D1 obtained in the third embodiment is strongly reduced in comparison to the interaction length WN of a conventional particle beam system.

### Implementation of the Second Multipole Field Generator 50 and the Third Multipole Field Generator 55

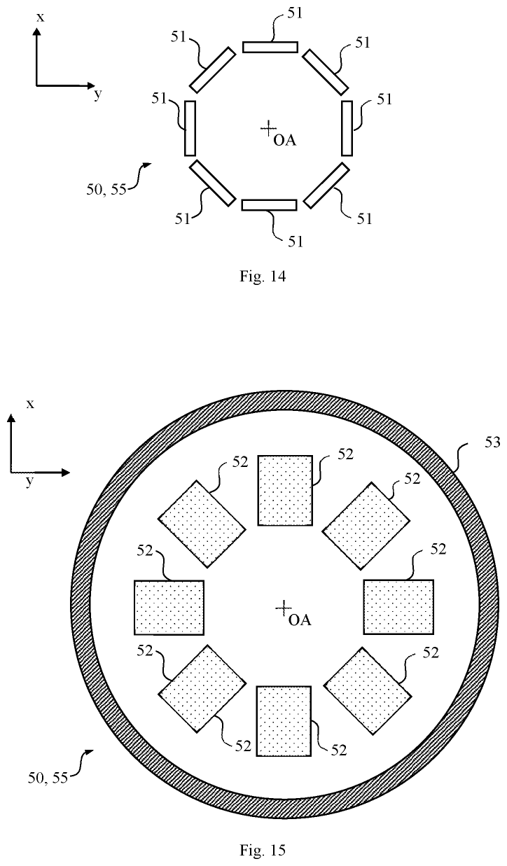

FIGS. 14 and 15 show schematic illustrations of exemplary implementations of the second multipole field generator 50 and the third multipole field generator 55. FIGS. 14 and 15 show a cross-section in a plane coplanar to the focal plane FP, i.e., in a plane perpendicular to the optical axis OA of the objective lens 13, at the locations of the second multipole field generator 50 and the third multipole field generator 55, respectively.

The following description refers to the second multipole field generator 50; however, the description also applies to the third multipole field generator 55. That is, the third multipole field generator 55 can have the same structural configuration as described for the second multipole field generator 50. However, the third multipole field generator 55 and the second multipole field generator 50 do not have to be implemented by the same structural configuration. For example, in principle, the third multipole field generator 55 could be implemented as illustrated in FIG. 14 whereas the second multipole field generator 50 could be implemented as illustrated in FIG. 15.

According to FIG. 14, the second multipole field generator 50 comprises eight electrodes 51 for providing electric poles. The electrodes 51 are arranged about a common center located at the optical axis OA of the objective lens 13. By appropriate application of voltages to the electrodes 51, various types of electric multipole fields can be generated. For example, the configuration allows to generate electric dipole fields and quadrupole fields of selectable strength and orientation. Consequently, the second multipole field generated by the second multipole field generator 50 can be rotated about the optical axis OA of the objective lens 13 together with the first multipole field generated by the first multipole field generator 18, thereby adjusting the orientation of the beam profile in the focal plane FP relative to the sample 2. For further reference, the electrodes 51 generate a second electric multipole field.

According to FIG. 15, the second multipole field generator 50 comprises eight coils 52 for providing magnetic poles. The coils 52 are arranged about a common center located at the optical axis OA of the objective lens 13. By appropriate application of currents to the coils 52, various types of magnetic multipole fields can be generated. For example, the configuration allows to generate magnetic dipole fields and quadrupole fields of selectable strength and orientation. Consequently, the second multipole field generated by the second multipole field generator 50 can be rotated about the optical axis OA of the objective lens 13 together with the first multipole field generated by the first multipole field generator 18, thereby adjusting the orientation of the beam profile in the focal plane FP relative to the sample 2. For further reference, the coils 52 generate a second magnetic multipole field.

While the second multipole field generator 50 illustrated in FIG. 14 comprises eight electrodes and the second multipole field generator 50 illustrated in FIG. 15 comprises eight coils, other implementations of the second multipole field generator 50 can comprise even more electrodes and coils. For example, the second multipole field generator 50 can comprise twelve or sixteen electrodes for generating the second electric multipole field. Further or alternatively, the second multipole field generator 50 can comprise twelve or sixteen coils for generating the second magnetic multipole field. Consequently, multipole fields of higher order can be generated for higher order manipulations of the beam 3.

The coils 52 can be wound around a non-magnetic material or can be coreless. Alternatively, the coils 52 can be wound around magnetic pole pieces guiding the magnetic field generated by the coils 52 and increasing the magnetic field strength at the optical axis OA of the objective lens 13. Some of the electrodes 51 can be supplied by the same voltage supply, thereby reducing the amount of independent voltage sources and increasing stability of the generated field at the cost of reduced flexibility. Some of the coils 52 can be connected to each other, for example connected in series, thereby reducing the amount of independent current sources and increasing stability of the generated field at the cost of reduced flexibility. An additional yoke 53 surrounding the coils 52 on the radial outside can be provided for supporting the magnetic flux (“closing” the magnetic flux path) and further increasing the magnetic field strength at the optical axis OA of the objective lens 13.

### Fourth Embodiment: Chromatic Aberration Correction in One Direction & Beam Widening by Same Field Generator

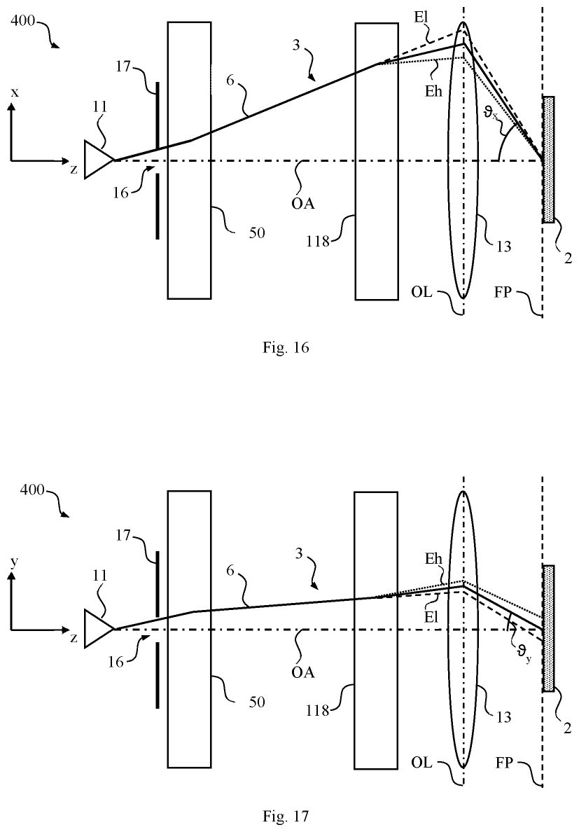

A particle beam system 400 according to a fourth embodiment is described below with reference to FIGS. 16 and 17. The fourth embodiment presents another different implementation of the mechanism for independently manipulating the maximum illumination angle ϑₓ of the beam 3 in the first plane (xz-plane) and the maximum illumination angle ϑ_{y} of the beam 3 in the second plane (yz-plane).

The particle beam system 400 differs from the particle beam system 300 according to the third embodiment in that the functions provided by the first multipole field generator 18 and the third multipole field generator 55 are provided by a single multipole field generator referred to as first multipole field generator 118. Accordingly, the mechanism for independently manipulating the maximum illumination angle ϑₓ of the beam 3 in the first plane (xz-plane) and the maximum illumination angle ϑ_{y} of the beam 3 in the second plane (yz-plane) is achieved by a two-stage direction-dependent focusing which is implemented by the first multipole field generated by the first multipole field generator 118 (second stage) and the second multipole field generated by the second multipole field generator 50 (first stage).

The first multipole field generator 118 has the same structure as the first multipole field generator 18 of the first to third embodiments illustrated in FIGS. 7 and 8; however, the first multipole field generator 118 is operated differently. Accordingly, the first multipole field generated by the first multipole field generator 118 and the first multipole field generated by the first multipole field generator 18 are different.

For example, the first multipole field generator 118 is operated to generate the first multipole field so that the first multipole field provides both the second stage of the direction-dependent focusing according to the third embodiment and the energy-dispersive focusing/defocusing according to the first embodiment. That is, the first multipole field generator 118 is configured and operated so that the chromatic aberration of the focusing by the objective lens 13 in the first direction (x-axis) is reduced and that the chromatic aberration of the focusing by the objective lens 13 in the second direction (y-axis) is increased and is further configured to generate the first multipole field so that the charged particles of the beam 3 are focused according to a selectable third focusing power in the first plane (xz-plane) and that the charged particles of the beam 3 are focused according to a selectable fourth focusing power in the second plane (yz-plane), wherein the third focusing power is greater than the fourth focusing power. For example, the fourth focusing power is selected to be equal to the negative third focusing power.

Similar to FIGS. 12 and 13, FIGS. 16 and 17 show the first and second plane in a rotating coordinate system rotating with the Larmor precession. That is, although illustrated in a flat plane, the x-axis and the y-axis rotate about the z-axis in dependence of the z-coordinate in accordance with the Larmor precession.

### Effect of Beam Widening in Plane OL

Similar to the third embodiment, the particle beam system 400 according to the fourth embodiment generates a non-circular beam shape as illustrated in FIG. 11, thus providing the same benefits.

In order to achieve a sufficient aspect ratio of the beam shape of the beam 3 in the objective lens 13, a distance between the second multipole field generator 50 and the first multipole field generator 118 along the optical axis OA of the objective lens 13 is sufficiently large. In some embodiments, aspect ratios of the beam shape of the beam 3 in the objective lens 13 provided by the mechanism for independently manipulating the maximum illumination angles range from about 2 to 5. Therefore, the distance between the second multipole field generator 50 and the first multipole field generator 118 is about 5 cm to 20 cm.

### Effect in Focal Plane FP, Beam Profile

Similar to the above embodiments, the particle beam system 400 according to the fourth embodiment generates a beam profile having a non-circular interaction profile 35 in the focal plane FP as illustrated in FIG. 6, thus providing the same benefits. Also, the interaction length W1 in the first direction D1 obtained in the fourth embodiment is strongly reduced in comparison to the interaction length WN of a conventional particle beam system.

### Adjusting the Orientation of the Beam Profile

The orientation of the beam profile of the beam 3 in the focal plane FP relative to the sample 2 can be adjusted by rotating the second multipole field generated by the second multipole field generator 50 and the first multipole field generated by the first multipole field generator 118.

### Improvement of First to Fourth Embodiments by Additional Octupole Field

The first to fourth embodiments described above each include the first multipole field generator 18 or 118 configured and operated to reduce chromatic aberration in the first direction D1 at the cost of decreased resolution in the second direction D2. When excited in this manner, the first multipole field generator 18 or 118 also generates a 4-fold astigmatism C₄ configured (i.e., with an appropriate orientation and an appropriate sign) to reduce effects of spherical aberration in the first direction D1, even without explicit generation of an octupole field. However, the inventors found that an additional octupole field is beneficial for approaching the optimum state represented in equation (3) (described further below) in all modes of operation and is used for performing an optimization procedure OP6 (described further below).

Therefore, the first to fourth embodiments described above can be improved as follows. Further to the generating of the first multipole field acting on the beam 3, the manipulating of the beam 3 (S3) further comprises: generating a fourth multipole field having an eight-pole component acting on the beam 3. The fourth multipole field comprises at least one of a fourth electric multipole field having an eight-pole component and a fourth magnetic multipole field having an eight-pole component. That is, the fourth multipole field can comprise the fourth electric multipole field having the eight-pole component or can comprise the fourth magnetic multipole field having the eight-pole component or can comprise both. The fourth multipole field is generated so as to reduce effects of spherical aberration.

The fourth electric multipole field having the eight-pole component can be generated by a field generator having at least eight electrodes. For example, the fourth electric multipole field can be generated by the first multipole field generator 18, 118 having eight electrodes 23 (see FIG. 8). The fourth magnetic multipole field having the eight-pole component can be generated by a field generator having at least eight coils. For example, the fourth magnetic multipole field can be generated by the first multipole field generator 18, 118 having eight coils 24 (see FIG. 8).

The fourth multipole field can be rotated about the optical axis OA by appropriate excitation of the eight electrodes 23 and the eight coils 24 of the first multipole field generator 18, 118 (see FIG. 8). In order to simultaneously generate the first multipole field having four electric poles and four magnetic poles and the fourth multipole field having the eight-pole component, the first multipole field generator 18, 118 can be configured to individually control each of the electrodes 23 and the coils 24, for example. However, other configurations are also conceivable. For example, the windings of the coils 24 can have multiple patterns, wherein one of the patterns provides windings for generating the four-pole component of the first magnetic multipole field and another one of the patterns provides windings for generating the eight-pole component of the fourth magnetic multipole field.

Alternatively, the fourth multipole field can be generated and rotated by a field generator having 16 electrodes and/or 16 coils, for example. Hereby the 16 electrodes (coils) can be arranged in a single plane perpendicular to the optical axis OA. Alternatively, a first set of 8 of the 16 electrodes (coils) can be arranged in a first plane perpendicular to the optical axis OA, and a second set of 8 of the 16 electrodes (coils) can be arranged in a second plane perpendicular to the optical axis OA, wherein the first and second plane are slightly separated along the optical axis OA. The first set of 8 electrodes (coils) and the second set of 8 electrodes (coils) can be rotated about the optical axis OA relative to each other, for example by approximately 22.5°.

When the first multipole field is rotated, the fourth multipole field is rotated the same. The rotation of the fourth multipole field can be achieved by appropriate excitation of the field generator generating the fourth multipole field. Alternatively, the field generator generating the fourth multipole field can be rotated.

### Fifth Embodiment: Monochromator & Beam Widening

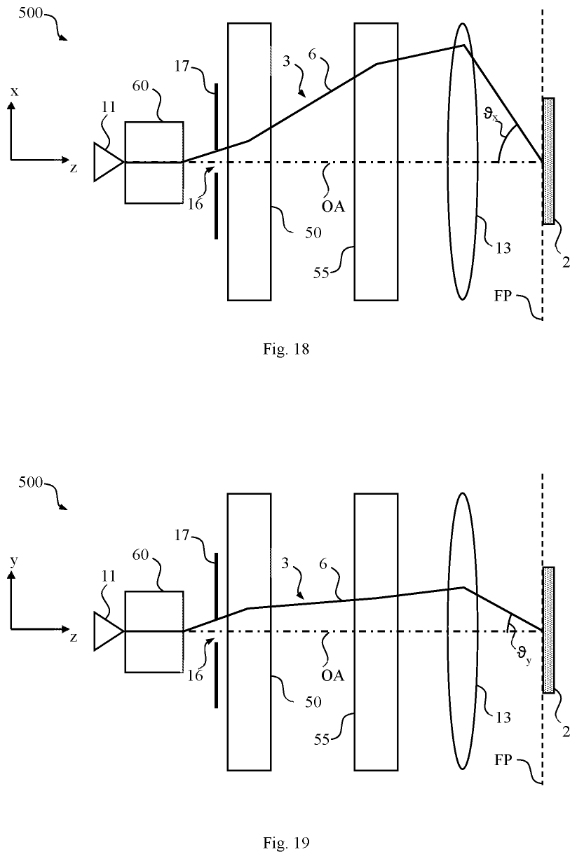

A particle beam system 500 according to a fifth embodiment is described below with reference to FIGS. 18 and 19. The particle beam system 500 according to the fifth embodiment differs from the particle beam system 300 according to the third embodiment in that the charged particle beam has a narrow energy bandwidth. Accordingly, chromatic aberration does not dominate the total aberration of the particle beam system, and thus, in the fifth embodiment, the first field generator 18 for compensating chromatic aberration according to the third embodiment is omitted. Further, the particle beam system 500 differs from the particle beam system 300 according to the third embodiment by further comprising a monochromator 60.

Similar to the third embodiment, the second multipole field generator 50 and the third multipole field generator 55 provide the mechanism for independently manipulating the maximum illumination angle ϑₓ of the beam 3 in the first plane (xz-plane) and the maximum illumination angle ϑ_{y} of the beam 3 in the second plane (yz-plane). This is achieved by the same two-stage direction-dependent focusing described with reference to the third embodiment.

As an alternative mechanism for independently manipulating the maximum illumination angle ϑₓ of the beam 3 in the first plane (xz-plane) and the maximum illumination angle ϑ_{y} of the beam 3 in the second plane (yz-plane), a (rotatable) aperture stop 19 having a non-circular aperture can be applied, as described above with reference to the second embodiment.

Similar to FIGS. 12 and 13, FIGS. 18 and 19 show the first and second plane in a rotating coordinate system rotating with the Larmor precession. That is, although illustrated in a flat plane, the x-axis and the y-axis rotate about the z-axis in dependence of the z-coordinate in accordance with the Larmor precession.

The monochromator 60 is disposed upstream of the second multipole field generator 50. The monochromator 60 is an energy filter configured to transmit charged particles having kinetic energies within a small predetermined energy bandwidth and to block charged particles having kinetic energies outside the predetermined energy bandwidth. For example, the monochromator 60 can be configured to reduce an energy width of the beam 3 provided by the particle source 11 to a value below 0.2 eV, such as below 0.1 eV, for example below 0.05 eV, about the predetermined kinetic energy En. The energy width is defined as full width at half maximum of a histogram of kinetic energies of the charged particles of the beam 3. The monochromator 60 can be implemented by a Wien filter, for example. Alternatively, the monochromator 60 is an energy compressor. Using electric and/or magnetic AC-fields, particles with a kinetic energy lower than the nominal kinetic energy are accelerated, and particles with a kinetic energy higher than the nominal kinetic energy are decelerated. No particles are blocked and the beam current is preserved, but at a high technical expenditure.

Due to the small energy bandwidth of the charged particles emerging from the monochromator 60, chromatic aberration of the objective lens 13 is not significant. However, in some systems, spherical aberration reduction can occur without the presence of a monochromator: If a high probe current is used, as in a beam inspection system, the illumination angle has to be increased to reach the desired probe current at the optimum resolution. Due to the cubic dependency of the spherical aberration on the illumination angle, the influence of the spherical aberration is strongly increased compared to the chromatic aberration with its linear dependency on the illumination angle. Consequently, in many cases, a total aberration of the particle beam system 500 is dominated by spherical aberration and an energy-dispersive focusing for chromatic aberration correction as provided in the first to fourth embodiment is not needed.

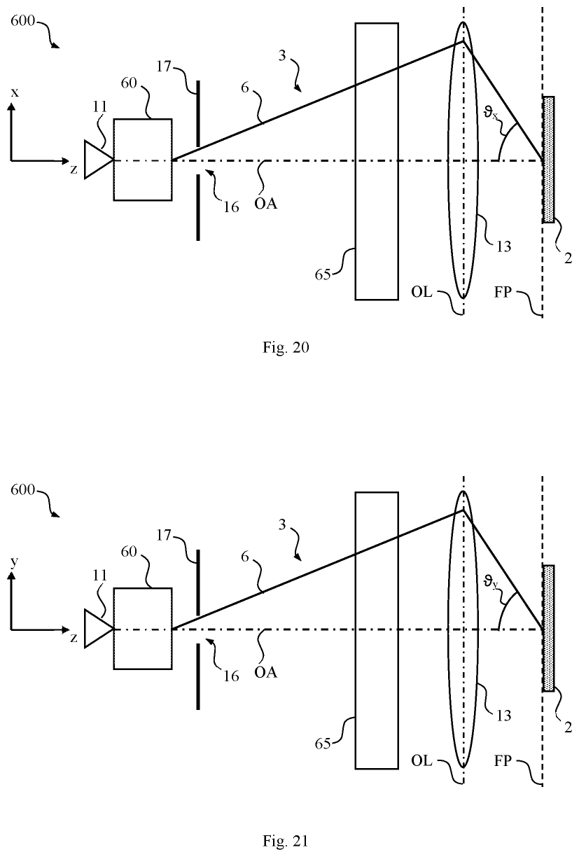

In FIGS. 18 and 19 (and FIGS. 20 and 21), the fundamental ray 6 is illustrated as to emerge from a virtual source at the exit of the monochromator 60. However, this is only a special case and not limiting. For example, the virtual source can be located inside the monochromator 60.

### Effect of Beam Widening

The inventors understood that, in an imaging system dominated by spherical aberration, adjusting a maximum illumination angle ϑₓ of a beam 3 in a first plane (xz-plane) to a first maximum illumination angle value and adjusting a maximum illumination angle ϑ_{y} of the beam 3 in a second plane (yz-plane) to a second maximum illumination angle value different from the first maximum illumination angle value manipulates the beam 3 so that the beam 3 has a beam profile having a non-circular interaction profile in the focal plane FP, the interaction profile in the focal plane FP having a shortest interaction length in a first direction (x-axis) and a largest line interaction length in a second direction (y-axis). Moreover, at the right choice of ϑₓ and ϑ_{y}, a smaller first interaction length W1 can be reached than in the case of ϑₓ=ϑ_{y}. Consequently, the particle beam system 500 according to the fifth embodiment can provide similar benefits as the embodiments disclosed above.

Also, the interaction length W1 in the first direction D1 obtained in the fifth embodiment is strongly reduced in comparison to the interaction length WN of a conventional particle beam system.

### Adjusting the Orientation of the Beam Profile

The orientation of the beam profile of the beam 3 in the focal plane FP relative to the sample 2 can be adjusted by rotating the second multipole field generated by the second multipole field generator 50 and the third multipole field generated by the third multipole field generator 55.

### Explanation of Effect in Focal Plane FP

A possible explanation of the effect of reduced interaction length of the beam 3 in the focal plane FP in the first direction (x-axis) by decreasing the second maximum illumination angle value (i.e., value of the maximum illumination angle ϑ_{y}) can be understood from Equations (1) below. Equations (1) describe a relation regarding spherical aberration between (i) a positional deviation (x, y) of the trajectory of a charged particle of the beam in the focal plane FP from the optical axis OA and (ii) the landing angles (αₓ, α_{y}) of the charged particles, where Cₛ denotes a spherical aberration coefficient.

$$x = {α}_{x} ( {α}_{x}^{2} + {α}_{y}^{2} ) \cdot {C}_{s} and y = {α}_{y} ( {α}_{x}^{2} + {α}_{y}^{2} ) \cdot {C}_{s} \qquad ( 1 )$$

As can be understood from Equations (1), decreasing the (average) landing angle α_{y} in the second plane (yz-plane) reduces the (average) deviation x of the trajectory from the optical axis in the first direction (x-axis), thereby reducing the interaction length in the focal plane FP in the first direction (x-axis). However, simultaneously, decreasing the (average) landing angle α_{y} in the second plane (yz-plane) also has two impacts on the deviation y of the trajectory from the optical axis in the second direction (y-axis), namely a decreasing impact due to reduced effects of spherical aberration in accordance with Equations (1) and an increasing impact due to increased aperture diffraction. Overall, the diffraction effect might dominate, thereby increasing the interaction length in the second direction (y-axis).

### Sixth Embodiment: Monochromator & Octupole Field Correction

A particle beam system 600 according to a sixth embodiment is described below with reference to FIGS. 20 to 23.

Similar to the first embodiment, the particle beam system 600 comprises the particle source 11, the objective lens 13 and the aperture stop 17 having the circular aperture 16. The particle beam system 600 further comprises the monochromator 60 according to the fifth embodiment. The particle beam system 600 further comprises an octupole-field generator 65 configured to generate an octupole field.

The octupole field generated by the octupole-field generator 65 is used to reduce effects of spherical aberration of the objective lens 13.

### Implementations of the Octupole-Field Generator 65

An exemplary implementation of the octupole-field generator 65 comprises sixteen electrodes for providing electric poles. By appropriate application of voltages to the sixteen electrodes, an electric octupole field of selectable strength and orientation about the optical axis OA of the objective lens 13 can be generated. The sixteen electrodes can be arranged in a single plane perpendicular to the optical axis OA. Alternatively, a first set of eight of the sixteen electrodes can be arranged in a first plane perpendicular to the optical axis OA, and a second set of eight of the sixteen electrodes can be arranged in a second plane perpendicular to the optical axis OA, wherein the first and second plane are slightly separated along the optical axis OA. The first set of eight electrodes and the second set of eight electrodes can be rotated about the optical axis OA relative to each other, for example by approximately 22.5°.

An exemplary implementation of the octupole-field generator 65 comprises sixteen coils for providing magnetic poles. By appropriate application of currents to the sixteen coils, a magnetic octupole field of selectable strength and orientation about the optical axis OA of the objective lens 13 can be generated. Alternatively, a first set of eight of the sixteen coils can be arranged in a first plane perpendicular to the optical axis OA, and a second set of eight of the sixteen coils can be arranged in a second plane perpendicular to the optical axis OA, wherein the first and second plane are slightly separated along the optical axis OA. The first set of eight coils and the second set of eight coils can be rotated about the optical axis OA relative to each other, for example by approximately 22.5°.

An exemplary implementation of the octupole-field generator 65 comprises eight electrodes 23 and eight coils 24, as illustrated in FIG. 8. The electrodes 23 generate an electric octupole-field; and the coils 23 generate a magnetic octupole-field. An octupole-force generated by the electric octupole-field is orientated like the electric octupole-field, while an octupole-force generated by the magnetic octupole-field is rotated by 22.5° against the magnetic (or electric) octupole-field. Therefore, even the first multipole field generator 18 of the first embodiment is capable of generating a rotatable octupole-force by superimposing an electric octupole field and a magnetic octupole field as implemented with reference to FIG. 8.

### Effect in Focal Plane FP, Beam Profile

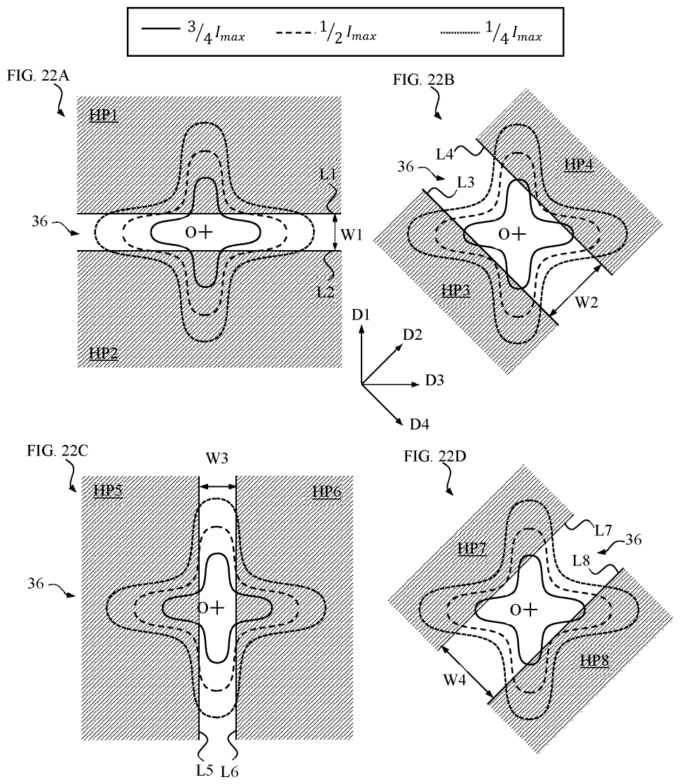

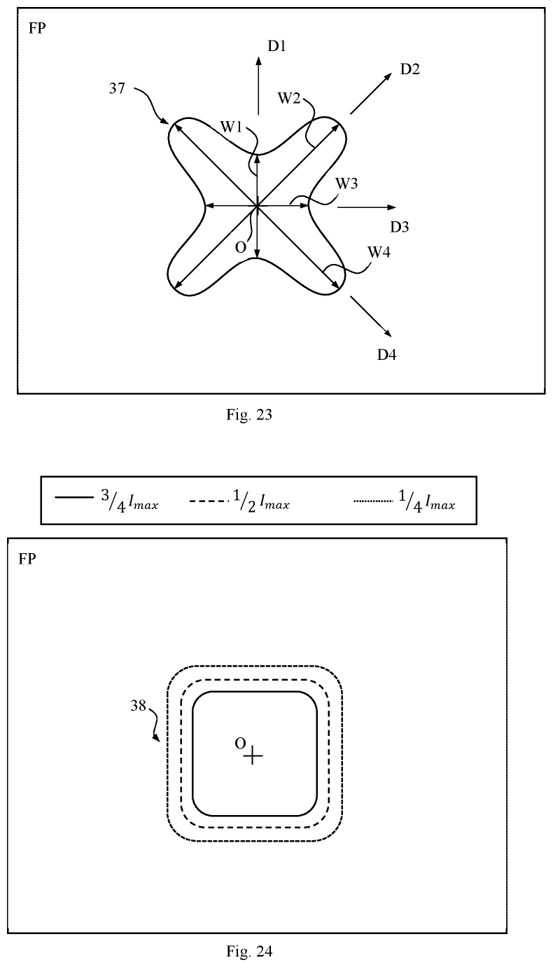

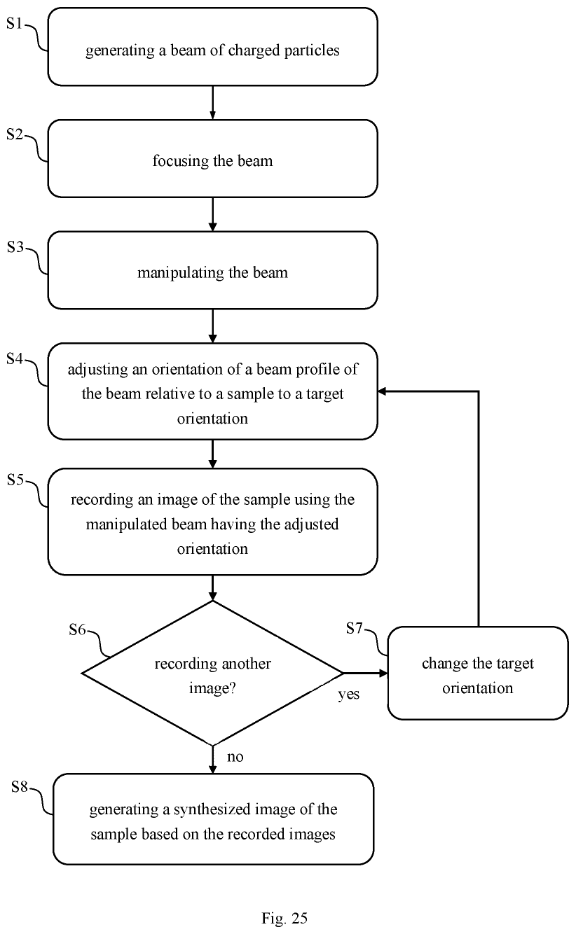

Referring to FIGS. 22A-22D and 23, the effect of the octupole field on the beam 3 is described. FIGS. 22A-22D show a schematic illustration of a resulting beam profile 36 of the beam 3 in the focal plane FP. The beam profile 36 of the beam 3 in the focal plane FP is schematically illustrated by three isolines and the center O of the intensity distribution of the beam 3, previously introduced with reference to FIGS. 5A and 5B. However, the beam profile 36 of the beam 3 illustrated in FIGS. 22A-22D differs considerably from the beam profile 34 illustrated in FIGS. 5A and 5B. In the example illustrated in FIGS. 22A-22D, the isolines have a shape of a cross having rounded vertices. The isolines are centered on the center O of the intensity distribution of the beam 3 in the focal plane FP.

Similar to FIGS. 5A and 5B, the beam profile 36 of the beam 3 in the focal plane FP will be characterized by the direction-specific interaction length. Accordingly, FIG. 22A shows a first straight L1 line perpendicular to a first direction D1 and a second straight line L2 perpendicular to the first direction D1. The first straight line L1 defines a first half-plane HP1. The first half-plane HP1 is located in the focal plane FP (focal plane FP is not illustrated in FIGS. 22A-22D) and contains 25% of a total intensity of the beam 3 in the focal plane FP. Similarly, the second straight line L2 defines a second half-plane HP2. The second half-plane HP2 is located in the focal plane FP and contains 25% of the total intensity of the beam 3 in the focal plane FP. The first half-plane HP1 and the second half-plane HP2 do not overlap. The first interaction length W1 is the distance, measured along the first direction D1, between the first straight line L1 and the second straight line L2.

Similarly, FIG. 22B shows a third straight L3 line perpendicular to a second direction D2 and a fourth straight line L4 perpendicular to the second direction D2. The third straight line L3 defines a third half-plane HP3. The third half-plane HP3 is located in the focal plane FP and contains 25% of the total intensity of the beam 3 in the focal plane FP. Similarly, the fourth straight line L4 defines a fourth half-plane HP4. The fourth half-plane HP4 is located in the focal plane FP and contains 25% of the total intensity of the beam 3 in the focal plane FP. The third half-plane HP3 and the fourth half-plane HP4 do not overlap. The second interaction length W2 is the distance, measured along the second direction D2, between the third straight line L3 and the fourth straight line L4.

Similarly, FIG. 22C shows a fifth straight L5 line perpendicular to a third direction D3 and a sixth straight line L6 perpendicular to the third direction D3. The fifth straight L5 defines a fifth half-plane HP5. The fifth half-plane HP5 is located in the focal plane FP and contains 25% of the total intensity of the beam 3 in the focal plane FP. Similarly, the sixth straight line L6 defines a sixth half-plane HP6. The sixth half-plane HP6 is located in the focal plane FP and contains 25% of the total intensity of the beam 3 in the focal plane FP. The fifth half-plane HP5 and the sixth half-plane HP6 do not overlap. The third interaction length W3 is the distance, measured along the third direction D3, between the fifth straight line L5 and the sixth straight line L6.

Similarly, FIG. 22D shows a seventh straight L7 line perpendicular to a fourth direction D4 and an eight straight line L8 perpendicular to the fourth direction D4. The seventh straight L7 defines a seventh half-plane HP7. The seventh half-plane HP7 is located in the focal plane FP and contains 25% of the total intensity of the beam 3 in the focal plane FP. Similarly, the eighth straight line L8 defines an eighth half-plane HP8. The eighth half-plane HP8 is located in the focal plane FP and contains 25% of the total intensity of the beam 3 in the focal plane FP. The seventh half-plane HP7 and the eighth half-plane HP8 do not overlap. The fourth interaction length W4 is a distance, measured along the fourth direction D4, between the seventh straight line L7 and the eighth straight line L8.

The first direction D1, the second direction D2, the third direction D3 and the fourth direction D4 are mutually different directions.

The beam 3 is manipulated by the octupole field so that the first interaction length W1 is significantly smaller than the second interaction length W2 and that the third interaction length W3 is significantly smaller than the fourth interaction length W4. For example, the octupole field is generated so that a ratio of the first interaction length W1 to the second interaction length W2 amounts to at most 1:1.2 and that a ratio of the third interaction length W3 to the fourth interaction length W4 amounts to at most 1:1.2. Optionally, the ratio of the first interaction length W1 to the second interaction length W2 amounts to at most 1:1.5 or at most 1:2.0. Optionally, the ratio of the third interaction length W3 to the fourth interaction length W4 amounts to at most 1:1.5 or at most 1:2.0.

As illustrated in FIGS. 22A-22D, the octupole field can be generated so that the first direction D1 and the third direction D3 are perpendicular to each other while the second direction D2 and the fourth direction D4 are perpendicular to each other.

FIG. 23 shows a schematic illustration of an interaction profile 37 of the beam 3 having the beam profile 36 illustrated in FIGS. 22A-22D. Please note that FIGS. 22A-22D and 23 have different scales, thus, in comparison to FIGS. 22A-22D, the same interaction length appears longer in FIG. 23. Similar to FIG. 6, the interaction profile 37 represents the direction-specific interaction lengths for all directions of the focal plane FP. For the beam profile 36 illustrated in FIGS. 22A-22D, this results in an interaction profile 37 having a shape of a lying cross (i.e., a cross rotated by 45°) having rounded vertices when the lines representing the interaction lengths are centered on a common center O.

As illustrated in FIGS. 22A-22D and 23, the interaction length W1 for the first direction D1 is shorter than the interaction length W2 for the second direction D2; and the interaction length W3 for the third direction D3 is shorter than the interaction length W4 for the fourth direction D4. Consequently, when using the beam 3 as a scanning microscope probe, in a resulting image, the maximum resolution in the first direction D1 is higher than the maximum resolution in the second direction D2; and the maximum resolution in the third direction D3 is higher than the maximum resolution in the fourth direction D4; while the resolutions in the first direction D1 and the third direction D3 are the same, and the resolutions in the second direction D2 and the fourth direction D4 are the same. Overall, the beam profile 36 is such that high resolution can be obtained simultaneously in two directions, i.e., in the first direction D1 and the third direction D3, at the cost of low resolution in two other directions, i.e., in the second direction D2 and the fourth direction D4.

Also, the interaction length W1 in the first direction D1 and the interaction length W3 in the third direction D3 obtained in the present embodiment are strongly reduced in comparison to the interaction length WN of a conventional particle beam system. Therefore, the present embodiment simultaneously provides a strongly improved resolution in the first direction D1 and in the third direction D3 in comparison to the conventional particle beam system having uniform resolution in all directions.

### Mode of Operation: Cross-Shaped Interaction Profile

In order to obtain the above-described effect, the octupole field is generated in a specific way described below. The influence of the octupole field sums up in the third order part of the aberration deviation in the beam profile as

$$x = {α}_{x} ( {α}_{x}^{2} + {α}_{y}^{2} ) \cdot {C}_{s} + {α}_{x} ( {α}_{x}^{2} - 3 {α}_{y}^{2} ) \cdot {C}_{4} \qquad ( 2 )$$

$$y = {α}_{y} ( {α}_{x}^{2} + {α}_{y}^{2} ) \cdot {C}_{s} - {α}_{y} ( 3 {α}_{x}^{2} - {α}_{y}^{2} ) \cdot {C}_{4}$$

In Equations (2) above, the aberration coefficient C₄ for a 4-fold astigmatism describes the strength of the octupole field, C_{S} is the spherical aberration coefficient, and αₓ and α_{y} denote landing angles along the x-axis and along the y-axis.

By adjusting the strength of the octupole field so that C₄ corresponds to C_{S}/3, Equation (2) becomes:

$$x = 4 / 3 \cdot {α}_{x}^{3} \cdot {C}_{s} \qquad ( 3 )$$

$$y = 4 / 3 \cdot {α}_{y}^{3} \cdot {C}_{s}$$

Accordingly, in comparison to the situation without octupole field, the aberration is strongly reduced on the diagonals of the x-y-coordinate system, while the aberration on the x-axes and y-axes is slightly increased. However, in the generation of the interaction profile the diagonals dominate the averaging process. This results in a cross-shaped beam profile as illustrated in FIGS. 22A-22D, and a rotated cross-shaped interaction profile illustrated in FIG. 23.

### Mode of Operation: Square-Like Interaction Profile

By adjusting the strength of the octupole field so that C₄ corresponds to approximately 0.17·C_{S}, the beam is manipulated into an approximately square-like beam profile 38 in the focal plane FP, which is schematically illustrated in FIG. 24. When machining a sample with a charged particle beam by milling, etching, or depositing, the beam profile is printed to the sample surface. A square-like beam profile can be desirable for writing the corners of rectangular structures.

### Adjusting the Orientation of the Beam Profile

The orientation of the beam profile of the beam 3 in the focal plane FP relative to the sample 2 can be adjusted by rotating the octupole field generated by octupole-field generator 65.

### Optimizing the Beam Profile

In the particle beam systems 100 to 600 described herein, multipole fields are generated und used for manipulating the beam profile of the beam 3. As explained with reference to FIGS. 5 and 22A-22D, the objective of the manipulating is to achieve a short first interaction length W1 in the first direction which is shorter than in a conventional particle beam system. The particle beam systems 100 to 600 described herein provide multiple different parameters that are used to obtain a short first interaction length W1 in the first direction. These parameters can be the parameters defining an excitation of the multipole field generators (first multipole field generator 18, 118; second multipole field generator 50; third multipole field generator 55; octupole-field generator 65), for example. Further, these parameters can be the maximum illumination angles, e.g., the maximum illumination angle ϑₓ of the beam 3 in the first plane (xz-plane) and the maximum illumination angle ϑ_{y} of the beam 3 in the second plane (yz-plane). For example, these parameters are the voltages applied to electrodes of the multipole field generators and the currents applied to coils of the multipole field generators.

Conventional particle beam systems are optimized to obtain high resolution in all directions of the focal plane. In terms of the beam profile illustrated in FIGS. 5 and 22A-22D, conventional particle beam systems are optimized to have equal interaction length in all directions of the focal plane. In contrast to this approach, the embodiments of the present disclosure are optimized to obtain high resolution in a single direction or two directions, thereby obtaining a higher resolution in this selected direction (these two selected directions) compared to the conventional particle beam systems. This effect comes at the price of worse resolution in other directions compared to the conventional particle beam systems.

Conventional particle beam systems use a stigmator (an electric or magnetic field generator capable of generating a weak, rotatable quadrupole field) to compensate for residual astigmatism which is generated by properties of optical elements, i.e., by mechanical tolerances and/or material inhomogeneities of an objective lens. The particle beam systems 100 to 600 described herein can also comprise such a stigmator for the same purpose. Alternatively, any of the multipole field generators (first multipole field generator 18, 118; second multipole field generator 50; third multipole field generator 55; octupole-field generator 65) can be used as a stigmator to generate a weak, rotatable, and electric or magnetic quadrupole field in addition to its primary purpose. This weak quadrupole field weakly focuses the charged particle beam 3 in a fifth direction D5 and weakly defocuses in a sixth direction D6, which is perpendicular to the fifth direction D5, and is configured to compensate for the residual astigmatism of the particle column 10. While the target orientations of the first direction D1, the second direction D2, the third direction D3, and the fourth direction D4 of the manipulated beam profile are selected to different values, the fifth direction D5 and the sixth direction D6 remain fixed.

According to a first optimization routine, the parameters are optimized to obtain a shortest interaction length in one single direction. FIGS. 5A and 5B illustrate an example of the beam profile 34 obtained by the first optimization routine, and FIG. 6 illustrates the resulting interaction profile 35 of the beam profile 34. As illustrated in FIG. 6, the shortest interaction length is the interaction length W1 for the first direction D1. That is, all available parameters are determined so that a shortest interaction length is obtained for one single direction in the focal plane FP.

According to a second optimization routine, the parameters are optimized to obtain short interaction lengths in two directions. FIGS. 22A-22D illustrate an example of the beam profile 36 obtained by the second optimization routine, and FIG. 23 illustrates the resulting interaction profile 37 of the beam profile 36. As illustrated in FIG. 23, the short(est) interaction lengths are the first interaction length W1 for the first direction D1 and the third interaction length W3 for the third direction D3. That is, all available parameters are determined so that two short interaction lengths for two different directions (i.e., one for each direction) are obtained.

The optimization can be performed by standard routines. For example, optimized values for the parameters can be obtained by trial and error, experiment, simulation or a combination thereof. The beam profile can be obtained by measuring the intensity distribution of the beam 3 in the focal plane FP and evaluating the measured data.

Depending on the particular configuration of the charged particle beam system and the intended application, the optimization can include any of the following steps that can be selectively and iteratively applied:
(OP1) Align the beam 3 to the optical axes of all optical elements by electrical or mechanical alignment.
(OP2) Adjust the multipole field generator 18, 118 to compensate the chromatic aberration in the first direction D1.
(OP3) Adapt the maximum illumination angle ϑₓ so that the superposition of diffraction and aberrations in the first direction D1 leads to a minimum interaction length W1. If direction-dependent beam widening is not available, the maximum illumination ϑ_{y} is adapted to the same value.
(OP4) If direction-dependent beam widening is available, adapt the maximum illumination angle ϑ_{y} (independently from ϑₓ) so that the superposition of diffraction and aberrations in the second direction D2 leads to a minimum interaction length W2.
(OP5) If direction-dependent beam widening is available, reduce the maximum illumination angle ϑ_{y} (independently from ϑₓ) so that the diffraction in the second direction D2 leads to an interaction length W2 that has a maximum allowed value, thereby reducing the interaction length W1 in the first direction D1.
(OP6) Adapt the 4-fold astigmatism C₄ by exciting an octupole field with the octupole field generator 65 or the multipole field generator 18, 118 so that the interaction length W1 in the first direction D1 adopts a minimum.
(OP7) Fine adjust defocus and astigmatism by changing the excitation of objective lens 13 (and stigmator if present) so that the resolution in the first direction D1 and the resolution in the direction perpendicular to the first direction D1 are the best.

Hereinabove, an influence of defocus and astigmatism was not discussed, because it makes explanations more complicated and figures less clear. Nevertheless, this influence can be numerically simulated or experimentally measured, so that the optimization procedure OP7 is feasible.

At a low landing energy, the chromatic aberration usually dominates the aberrations of a particle beam system. The chromatic aberration, at least in the first direction D1, should be compensated, like shown in the exemplary particle beam systems 100, 200, 300, and 400. If no mechanism for generating direction-dependent beam widening is provided, like in the exemplary particle beam system 100, the optimization procedures OP1, OP2, OP3, and OP7 should be iteratively applied.

If a mechanism for generating a rotatable octupole field are provided, like by an additional octupole field generator 65 or a corresponding excitation mechanism for the multipole field generator 18, the effects of spherical aberration in the first direction D1 can be reduced by introducing a 4-fold astigmatism C₄, as discussed with equation (2). Here the optimization procedures OP1, OP2, OP3, OP6, and OP7 should be iteratively applied.

If one is interested in a maximum ratio W1/W2, a mechanism for a rotatable, direction-dependent beam widening can be provided, like shown in the exemplary particle beam systems 200, 300, and 400. Here the optimization procedures OP1, OP2, OP3, OP4, and OP7 should be iteratively applied.

If the interaction length W1 in the first direction D1 should be further reduced, and a certain interaction length W2 in the second direction D2 is allowed, the effects of spherical aberration in the first direction D1 can be reduced by changing the beam widening, as discussed with equation (1). Here the optimization procedures OP1, OP2, OP3, OP5, and OP7 should be iteratively applied.

If the interaction length W1 in the first direction D1 should be further reduced, and one is interested in a maximum ratio W1/W2, a mechanism for generating a rotatable octupole field can be provided, like by an additional octupole field generator 65 or a corresponding excitation mechanism for the multipole field generator 18, 118. Thereby the effects of spherical aberration in the first direction D1 can be reduced by introducing a 4-fold astigmatism C₄, as discussed with equation (2). Here the optimization procedures OP1, OP2, OP3, OP4, OP6, and OP7 should be iteratively applied.

It should be noted that the multipole field generator 18, when excited for a chromatic aberration compensation in the first direction D1, already produces a 4-fold astigmatism C₄ with the right orientation and sign for the reduction of the effects of spherical aberration in the first direction D1, without any octupole field present. However, to come near to the optimum state shown in equation (3) in all modes of operation, an additional octupole field is used to perform the optimization procedure OP6.

Additionally, if the direction-dependent beam widening is used according to optimization procedure OP4, there is already a reduction of the effects of spherical aberration in the first direction D1 as discussed with equation (1). Switching optimization procedures from OP4 to OP5 can further reduce the effects of spherical aberration in the first direction D1.

If using a high landing energy, a monochromator, or a high beam current (like in a beam inspection system), the spherical aberration usually dominates the aberrations of a particle beam system. Here a compensation of the chromatic aberration is not needed.

In such a system, the effects of spherical aberration can be reduced in one direction by direction-dependent beam widening, like shown in the exemplary particle beam system 500. Here the optimization procedures OP1, OP3, OP5, and OP7 should be iteratively applied.

Alternatively, the effects of spherical aberration can be reduced in two directions by 4-fold astigmatism, like shown in the exemplary particle beam system 600. Here the optimization procedures OP1, OP3, OP6, and OP7 should be iteratively applied.

It depends on the type of application which of these two methods for the reduction of the effects of spherical aberration should be chosen, but the optimized resolution in two directions at the same time can be desirable for the use of the 4-fold astigmatism.

### Alignment of Multipole Fields

In the particle beam systems described herein, multiple electric and/or magnetic fields are generated. Proper alignment of these fields is thus used to obtain the desired improvements.

Due to mechanical tolerances and inhomogeneity of magnetic material properties, the center of an electric multipole field, the center of a magnetic multipole field and the beam position might deviate from each other. In order to align these, electric and magnetic dipole fields overlapping with the multipole fields can be generated to shift the multipole fields.

Shared supplies for oppositely arranged electrodes/coils, i.e., electrodes and coils arranged opposite to each other across the optical axis of the respective field generator (where the polarities of opposing coils are chosen so that their dipole fields in the center of the multipole practically cancel out), improve stability of the generated fields, but have the drawback of preventing dipole fields for alignment. For the magnetic field, this issue can be addressed by using additional coils, referred to as alignment coils, having a small maximum excitation (where the polarities of opposing alignment coils are chosen so that their dipole fields in the center of the multipole add up). The alignment coils are driven with a small maximum current, just as high to enable the alignment of the magnetic multipole field. Consequently, deflection induced by current noise and drift in these coils will be also small, so that the overall system stability is maintained. A smaller maximum current or less alignment coil windings lead to a smaller deflection by the noise and drift of the current sources but reduce the maximum shift of the center of the magnetic multipole field and, therefore, the allowable mechanical tolerance range.

There are two ways to generate the electric dipole field for aligning the electric multipole field when using shared voltage supplies, here presented for the example of eight electrodes, but the principles of the solution can be applied to any other number of electrodes. The first way is to insert a floating voltage source with a small output range in series between every electrode and its corresponding base voltage supply output. These floating voltage sources provide the electrodes with small alignment voltages. Applying opposite alignment voltages, i.e., alignment voltages of the same magnitude but different sign, to oppositely arranged electrodes produces a weak dipole field, which is sufficient for the alignment of the electric multipole field but does not generate too much deflection by noise and drift of the alignment voltage sources. For this solution eight additional floating voltage sources are used.

The second way is to use a resistor network to mix the signals on the electrodes to produce a weak dipole field and a strong multipole field. Assume that four voltage sources with complementary outputs and identical output ranges are used, the outputs QC+ and QC− are available for a first quadrupole field, outputs QS+ and QS− for a second quadrupole field, outputs DX+ and DX− for the first dipole field, and outputs DY+ and DY− for the second dipole field. When numbering the electrodes counterclockwise from U1 to U8, the electrodes are connected to these outputs by resistors with values listed in Table 1. The base value R may be chosen appropriately.

TABLE 1
Resistor network values for generating electric dipole
and quadrupole fields from shared voltage supplies

| | QC+ | QC− | QS+ | QS− | DX+ | DX− | DY+− | DY− |
|---|---|---|---|---|---|---|---|---|
| U1 | R | — | — | — | 10 R | — | — | — |
| U2 | — | — | R | — | 14 R | — | 14 R | — |
| U3 | — | R | — | — | — | — | 10 R | — |
| U4 | — | — | — | R | — | 14 R | 14 R | — |
| U5 | R | — | — | — | — | 10 R | — | — |
| U6 | — | — | R | — | — | 14 R | — | 14 R |
| U7 | — | R | — | — | — | — | — | 10 R |
| U8 | — | — | — | R | 14 R | — | — | 14 R |

Many resistor network configurations are possible, but the configuration listed in Table 1 results in the minimum number of resistors. The strength of the dipole field can be changed by scaling the numbers 10 and 14 in the table by the same factor. Larger values lead to a smaller deflection by the noise and drift of the voltage supplies but reduce the maximum shift of the center of the electric quadrupole field and, therefore, the allowable mechanical tolerance range.

The resistor network does not necessarily need to be connected directly to the electrodes. Instead, the output range of the original amplifiers may be reduced, and additional amplifiers may be inserted into the lines between the resistor network and the electrodes. In this way the resistors can work at a lower voltage, while simple amplifiers usually do not introduce too much noise or drift; but the optimum solution depends on the layout of the complete imaging system.

Alternatively, external deflection elements can be inserted in front of one or more multipole fields. With these deflection elements, the central trajectory of the charged particle beam 3 can be manipulated to pass the multipole fields at their real centers. When using a double deflection element, even the direction can be adjusted, so that the real axis of the multipole field is used as an optical axis over its whole length. This can be desirable for a multipole field which is long compared to its bore diameter. Since only weak deflection elements are involved, noise and drift are not a problem.

If the center of the magnetic multipole does not coincide with the center of the electric multipole due to magnetic inhomogeneities, external deflection elements are not sufficient. Weak alignment coils in the multipole can be used to shift the axis of the magnetic multipole field to the axis of the electric multipole field, like described earlier.

However, even if the centers of all electric and magnetic quadrupole fields are shifted to the position of the beam, or the position of the beam to the respective center of each quadrupole field, a small residual image shift may still occur when the orientation of the probe shape is changed. Therefore, when acquiring a series of images, every image can be moved back to its non-shifted position. This non-shifted position can be determined by a cross-correlation between subsequent images or between every image and a reference image, but noise can deteriorate the result. To reduce the influence of noise, the image shifts determined by the cross-correlation can be fitted by the formula

$$X ( i ) = A \cdot ( cos ( 2 \cdot ( β \cdot i + γ ) ) - cos ( 2 \cdot ( β \cdot n + γ ) ) ) + BX \cdot ( T ( i ) - T ( n ) ) ,$$

$$Y ( i ) = A \cdot ( sin ( 2 \cdot ( β \cdot i + γ ) ) - sin ( 2 \cdot ( β \cdot n + γ ) ) ) + BY \cdot ( T ( i ) - T ( n ) ) ,$$

where X(i), Y(i) is the image shift of the image with index i within the image series relative to the reference image with index n, A is the residual shift amplitude induced by the combined action of all multipole fields, β is an angular step size in the orientation of the beam profile, γ is the residual shift orientation induced by the combined action of all multipole fields, BX, BY are drift velocities along the x-axis and y-axis, respectively, and T(i) is the starting time of the acquisition of the image with index i. Since β, n, and T(i) are known, the parameters A, γ, BX, and BY can be used to fit the determined image shifts. Hence, all shift data generated from the application of the cross-correlation function is now projected to only these four parameters, so that a strong averaging is done, and the influence of noise is effectively reduced.

### First Application: Improved Image Resolution in any Direction

FIG. 25 shows a flowchart illustrating a first method of operating the particle beam systems described herein. The objective of the first method is to obtain an image of a sample 2 having improved resolution in any direction (i.e., high resolution in all directions). Steps S2 to S4 of the first method do not have to be performed in the order indicated by arrows of the flowchart. Instead, the steps S2 to S4 of the first method can be performed in any order. For example, the steps S2 to S4 of the first method can be performed simultaneously.

According to step S1, the first method comprises generating a beam 3 of charged particles (e.g., electrons). For example, the step S1 can be performed by the particle source 11 of the particle beam systems described herein.

After step S1, according to step S2, the first method further comprises focusing the beam 3 into a focal plane FP. For example, the step S2 can be performed by the objective lens 13 of the particle beam systems described herein.

According to step S3, the first method further comprises manipulating the beam 3 so that the beam 3 has a beam profile in the focal plane FP having a non-circular interaction profile in the focal plane FP. For example, according to the first embodiment, the step S3 can be performed by the first multipole field generator 18. Further, according to the second embodiment, the step S3 can be performed by the first multipole field generator 18 and the aperture stop 19 having the non-circular aperture. Further, according to the third embodiment, the step S3 can be performed by the first multipole field generator 18, the second multipole field generator 50 and the third multipole field generator 55. Further, according to the fourth embodiment, the step S3 can be performed by the first multipole field generator 118 and the second multipole field generator 50. Further, according to the fifth embodiment, the step S3 can be performed by the second multipole field generator 50 and the third multipole field generator 55. Further, according to the sixth embodiment, the step S3 can be performed by the octupole field generator 65. Step S3 causes the beam 3 to have a shortest interaction length along the first direction and a largest interaction length along the second direction (see FIG. 6). In some cases, step S3 causes the beam 3 to have two (or more) short interaction lengths (e.g., short interaction lengths W1 and W3 along the first and third directions, respectively, see FIG. 23) at the cost of the beam 3 having two (or more) long interaction lengths (e.g., long interaction lengths W2 and W4 along the second and fourth directions, respectively, see FIG. 23).

According to step S4, the first method further comprises adjusting an orientation of the beam profile in the focal plane FP relative to the sample 2 (located in the focal plane FP) to a target orientation. For example, the step S4 can be performed by rotating the sample 2. Rotating the sample 2 can be performed by controlling the sample stage 4 to rotate the sample 2, for example. Further, according to the first embodiment, the step S4 can be performed by rotating the first multipole field generated by the first multipole field generator 18. Further, according to the second embodiment, the step S4 can be performed by rotating the first multipole field generated by the first multipole field generator 18 and rotating the aperture stop 19 having the non-circular aperture. Further, according to the third embodiment, the step S4 can be performed by rotating the first multipole field generated by the first multipole field generator 18, rotating the second multipole field generated by the second multipole field generator 50 and rotating the third multipole field generated by the third multipole field generator 55. Further, according to the fourth embodiment, the step S4 can be performed by rotating the multipole field generated by the first multipole field generator 118 and rotating the second multipole field generated by the second multipole field generator 50. Further, according to the fifth embodiment, the step S4 can be performed by rotating the second multipole field generated by the second multipole field generator 50 and rotating the third multipole field generated by the third multipole field generator 55. Further, according to the sixth embodiment, the step S4 can be performed by rotating the octupole field generated by the octupole field generator 65. Step S4 causes the first direction (i.e., direction of highest resolution) to be orientated along a selected target orientation with respect to the sample 2.

According to step S5, the first method further comprises recording an image of the sample 2 located in the focal plane FP using the manipulated beam 3 (i.e., the beam having the beam profile manipulated according to step S3) having the adjusted orientation (i.e., adjusted according to step S4). The image recorded in step S5 has a highest resolution along the first direction (and the third direction) because the shortest interaction length of the interaction profile of the beam 3 in the focal plane FP is orientated along the first direction (and the third direction). The image recorded in step S5 has a worst resolution along the second direction (and the fourth direction) because the largest interaction length of the interaction profile of the beam 3 in the focal plane FP is orientated along the second direction (and the fourth direction).

For example, the recording of the image according to step S5 can comprise: maintaining the adjusted orientation while directing the manipulated beam 3 to a plurality of locations of the sample 2; detecting interaction products of an interaction of the manipulated beam 3 with the sample 2 during the directing of the manipulated beam 3 to the plurality of locations of the sample 2; and generating the image based on the detected interaction products. Maintaining the adjusted orientation mechanism to not change the orientation of the beam profile of the beam 3 relative to the sample 2. The detecting of the interaction products can be performed by the detection system 40 of the particle beam systems described herein. The generating of the image can be performed by the controller 30 of the particle beam systems described herein.

According to step S6, the first method further comprises determining whether another image is to be recorded. For example, the step S6 can be performed by the controller 30 of the particle beam systems described herein. If the determination in step S6 is to record another image (yes at step S6), step S7 is performed next. If the determination in step S6 is to not record another image (no at step S6), step S8 is performed next.

According to step S7, the first method further comprises changing the target orientation. For example, the step S7 can be performed by the controller 30 of the particle beam systems described herein. Subsequent to step S7, steps S4 to S7 are repeated until the determination in step S6 is to not record another image. As a result, a plurality of images of the sample 2 are recorded at different orientations of the beam profile of the beam 3 in the focal plane FP relative to the sample 2. Consequently, the direction of highest resolution differs among the recorded images. When using the beam profile illustrated in FIGS. 5A and 5B, where the beam profile exhibits only one direction providing maximum resolution (i.e., the first direction), many images are recorded to cover a near 180° rotation of the target orientation. In contrast, when using the beam profile illustrated in FIGS. 22A-22D, where the beam profile exhibits two directions providing maximum resolution, less images are recorded to cover a near 90° rotation of the target orientation.

According to step S8, the first method further comprises calculating a synthesized image of the sample 2 based on the recorded images (i.e., the images recorded in step S5). For example, the step S8 can be performed by the controller 30 of the particle beam systems described herein.

A variety of suitable algorithms can be used for the calculating of the synthesized image of the sample 2 based on the recorded images. Suitable algorithms can use the fact that the resolution of each of the recorded images is not uniform but direction dependent. That is, each of the recorded images exhibits a highest resolution along the first direction defined by the interaction profile of the beam 3 in the focal plane FP during the recording of the respective image and exhibits a worst resolution along the second direction defined by the beam profile of the beam 3 in the focal plane FP during the recording of the respective image. When using the beam profile illustrated in FIGS. 22A-22D, each of the recorded images exhibits a highest resolution along the first and third direction defined by the beam profile of the beam 3 in the focal plane FP during the recording of the respective image and exhibits a worst resolution along the second and fourth direction defined by the beam profile of the beam 3 in the focal plane FP during the recording of the respective image. Due to steps S7 and S4, the orientation of the beam profile of the beam 3 in the focal plane FP is changed between subsequent recordings in step S5. Consequently, the directions of highest resolution in the recorded images are different from each other. However, by appropriate combination of the recorded images, a synthesized image having improved resolution in all directions can be obtained. Hereinafter, two exemplary algorithms are described.

### Non-Uniform Weighting in Dependence of the Target Orientations

By appropriately weighting high-resolution contributions of the recorded images higher than low-resolution contributions of the recorded images, the synthesized image can exhibit high resolution in any direction.

According to a specific example, calculating the synthesized image comprises: weighting the recorded images using non-uniform weight distributions, wherein orientations of the weight distributions are selected to correspond to the target orientations; and merging the weighted images.

According to this example, the recorded images exhibiting a direction-dependent maximum resolution are weighted using non-uniform weight distributions and the weighted images are merged (e.g., averaged), thereby generating the synthesized image. For example, each of the recorded images is weighted by (e.g., multiplied with) one of the non-uniform weight distributions, and the weighted images are merged. The expression non-uniform weight distribution mechanism that different pixels/areas of an image are weighted by different strengths (e.g., different values). Exemplifying the weight distribution by a scalar field, a non-uniform scalar field would be characterized by including different values.

Further, each of the non-uniform weight distributions is associated with a direction/orientation which is characteristic for the particular weight distribution. Accordingly, based on the orientation of the weight distribution, different pixels/areas of an image are weighted with different strengths. By selecting the orientations of the non-uniform weight distributions to correspond to the target orientations, i.e., the directions of maximum resolution in the recorded images, the non-uniform weight distributions allow to increase a contribution of pixels/areas exhibiting high maximum resolution of each image to the synthesized image while a contribution of pixels/areas exhibiting low maximum resolution of each image is decreased. Thus, high maximum resolution pixels/areas of the recorded images contribute more to the synthesized image than low maximum resolution pixels/areas of the recorded images, thereby increasing the maximum resolution in any direction.

According to another specific example, the calculating of the synthesized image comprises weighting the recorded images using non-uniform weight distributions wᵢ(\vec{k}) and merging the weighted images. According to a specific example, the weight distributions wᵢ(\vec{k}) fulfil wᵢ(\vec{k}_{i,1})>wᵢ(\vec{k}_{i,2}), wherein i represents an index identifying an i-th one of the recorded images and ranges over all of the recorded images, wᵢ(\vec{k}_{i,1}) represents a weight for a spatial-frequency domain component of the i-th recorded image at spatial-frequency \vec{k}_{i,1}, wᵢ(\vec{k}_{i,2}) represents the weight for the spatial-frequency domain component of the i-th recorded image at spatial-frequency \vec{k}_{i,2}, \vec{k}_{i,1} represents a spatial-frequency of magnitude K in a spatial-frequency domain direction corresponding to the first direction, and \vec{k}_{i,2} represents a spatial-frequency of magnitude K in a spatial-frequency domain direction corresponding to the second direction.

When using the beam profile illustrated in FIGS. 22A-22D, according to a specific example, the weight distributions wᵢ(\vec{k}) further fulfil wᵢ(\vec{k}_{i,3})>wᵢ(\vec{k}_{i,4}), wherein wᵢ(\vec{k}_{i,3}) represents a weight for a spatial-frequency domain component of the i-th recorded image at spatial-frequency \vec{k}_{i,3}, wᵢ(\vec{k}_{i,4}) represents the weight for the spatial-frequency domain component of the i-th recorded image at spatial-frequency \vec{k}_{i,4}, \vec{k}_{i,3} represents a spatial-frequency of magnitude K in a spatial-frequency domain direction corresponding to the third direction, and \vec{k}_{i,4} represents a spatial-frequency of magnitude K in a spatial-frequency domain direction corresponding to the fourth direction.

According to another specific example, one non-uniform weight distribution is used for weighting all of the recorded images, but the orientation of the non-uniform weight distribution is changed for each weighting to correspond to the target orientation with which the respective image was recorded. In other words, for weighting a particular one of the recorded images, the non-uniform weight distribution is rotated to match the target orientation with which the particular image was recorded, and then the rotated non-uniform weight distribution is applied to the particular recorded image to form a weighted image.

### Deconvolution Algorithms

Generating the synthesized image based on the recorded images can involve algorithms of joint deconvolution, in which the recorded images are combined considering orientation-dependent non-uniform point spread functions (PSF). Examples of such algorithms include weighted averaging using rotation-specific point spread functions and Richardson-Lucy deconvolution.

According to a specific example, calculating the synthesized image comprises: convolving the recorded images using non-uniform point spread functions, wherein orientations of the point spread functions are selected to correspond to the target orientations; and merging the convolved images.

According to this example, the recorded images exhibiting a direction-dependent maximum resolution are convolved using non-uniform point spread functions and the convolved images are merged (e.g., averaged), thereby generating the synthesized image. For example, each of the recorded images is convolved by one of the non-uniform point spread functions, and the convolved images are merged. The expression non-uniform point spread functions mechanism that the point spread functions differ from each other. For example, the point spread functions can correspond to a same point spread function rotated to different directions corresponding to the target orientations.

Further, each of the non-uniform point spread functions is associated with a direction/orientation which is characteristic for the particular point spread function. Accordingly, based on the orientation of the point spread function, different pixels/areas of an image are weighted with different strengths. By selecting the orientations of the non-uniform point spread functions to correspond to the target orientations, i.e., the directions of maximum resolution in the recorded images, the non-uniform point spread functions allow to increase a contribution of pixels/areas exhibiting high maximum resolution of each image to the synthesized image while a contribution of pixels/areas exhibiting low maximum resolution of each image is decreased. Thus, high maximum resolution pixels/areas of the recorded images contribute more to the synthesized image than low maximum resolution pixels/areas of the recorded images, thereby increasing the maximum resolution in any direction.

Note that convolving with a given point spread function is equivalent to deconvolving with an inverse of the given point spread function. In other words, instead of convolving the recorded images, the recorded images can be deconvolved with another point spread function and the deconvolved images can be merged.

### Second Application: Improved Image Resolution in One Direction

FIG. 26 shows a flowchart illustrating a second method of operating the particle beam systems described herein. The objective of the second method is to obtain an image of a sample 2 having improved resolution in a single direction of particular interest. For example, for analyzing distances of a line structure on a sample comprising a plurality of separated parallel lines, high resolution of an image of the sample along a direction perpendicular to the direction of the lines is of particular interest whereas high resolution in a direction parallel to the direction of the lines is not of particular interest. In such use cases, high resolution in a single direction is more important than mediocre resolution in all directions.

The second method comprises the steps S1 to S5 of the first method described with reference to FIG. 25. Reference is made to the corresponding description. Steps S2 to S4 of the second method do not have to be performed in the order indicated by arrows of the flowchart. Instead, the steps S2 to S4 of the second method can be performed in any order, provided that step S9 is performed prior to step S4. For example, the steps S2 to S4 of the second method can be performed simultaneously.

According to step S9 to be performed before step S4, the second method further comprises selecting the target orientation based on an orientation of a structure on the sample. For example, the target orientation can be selected so that, in step S4, the first direction (i.e., the direction along which the interaction profile of the beam 3 in the focal plane FP has the shortest interaction length) is orientated perpendicular to a line structure on the sample 2. For example, the step S9 can be performed by the controller 30 of the particle beam systems described herein. By selecting the target orientation, the direction of highest resolution of the image to be recorded in step S5 can be selected as desired. For example, in a chip fabrication process, an orientation of a wafer in the fabrication process and an orientation of structures on the wafers are held in a controller controlling the chip fabrication process. Consequently, the target orientation may be defined based on a specification of the chip fabrication process. For example, in an experimental setup, an orientation of structures to be analyzed in more detail based on an image obtained by the second method can be obtained based on an image of the structures obtained by conventional approaches.

When the interaction pattern of the beam is manipulated to provide improved resolution in two different directions D1 and D3, as in the example of the sixth embodiment, these two directions D1 and D3 can be adapted to the structure on the sample 2. For example, when the structure on the sample 2 predominantly has lines arranged in a first structure direction (e.g., a horizontal direction) and lines arranged in a second structure direction (e.g., a vertical direction), these lines can be resolved best when the direction D1 is perpendicular to the first structure orientation (e.g., the direction D1 is perpendicular to the horizontal direction) and the direction D3 is perpendicular to the second structure direction (e.g., the direction D3 is perpendicular to the vertical direction). This benefit can be achieved by, in step S3, manipulating the beam so that the first direction D1 and the third direction D3 of the beam interaction pattern are arranged relative to each other in a pattern corresponding to the arrangement pattern of the structure directions and performing step S9.

Subsequent to step S9, according to the step S4, an orientation of the beam profile in the focal plane FP relative to the sample 2 is adjusted to the target orientation selected in step S9.

Subsequent to step S4, according to the step S5, an image of the sample 2 located in the focal plane FP is recorded using the manipulated beam 3 (i.e., the beam having the beam profile manipulated according to step S3) having the adjusted orientation (i.e., adjusted according to step S4).

Therefore, an image of the sample 2 having improved resolution in a single direction which is of particular interest can be recorded by the second method.

In some implementations, the controller 30 can include one or more data processors for processing data, one or more storage devices for storing data, and/or one or more computer programs including instructions that when executed by the controller 30 cause the controller 30 to carry out the methods described herein.

In some implementations, the controller 30 can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described systems and methods by operating on input data and generating output. Alternatively or additionally, the program instructions can be encoded on a propagated signal that is an artificially generated signal, e.g., a machine-generated electrical, optical, or electromagnetic signal, that is generated to encode information for transmission to suitable receiver apparatus for execution by a programmable processor. In some implementations, the operations associated with processing of data described herein can be performed by one or more programmable processors executing one or more computer programs to perform the functions described herein. A computer program can be written in any form of programming language, including compiled or interpreted languages, and it can be deployed in any form, including as a stand-alone program or as a module, component, subroutine, or other unit suitable for use in a computing environment.

### Further Aspects of the Disclosure and its Embodiments

The above described embodiments are directed to charged particle beam microscopes, for example electron beam microscopes. However, alternatively, each of the embodiments can be directed to an ion beam microscope or an inspection system.

Hereinabove, several different embodiments of the disclosure are described. However, the particular configurations of these embodiments can be combined. Further, some parts of these particular configurations of these embodiments can be omitted.

1. A method, comprising:
a) using a particle beam system to generate a beam of charged particles;
b) using an objective lens of the particle beam system to focus the beam into a focal plane;
c) manipulating the beam into a beam profile in which a ratio of a first interaction length to a second interaction length is at most 1:1.2;
d) adjusting an orientation of the beam profile in the focal plane relative to a sample to a target orientation;
e) using the manipulated beam having the adjusted orientation to record an image of the sample located in the focal plane;
f) repeating d) and e) using at least one target orientation different from the previously used target orientations; and
g) calculating a synthesized image of the sample based on the recorded images,
wherein:
the first interaction length is a distance, measured along a first direction, between a first straight line and a second straight line;
the first straight line is perpendicular to the first direction;
the second straight line is perpendicular to the first direction;
the first straight line defines a first half-plane;
the first half-plane is in the focal plane;
the first half-plane contains 25% of a total intensity of the beam in the focal plane;
the second straight line defines a second half-plane;
the second half-plane is in the focal plane;
the second half-plane contains 25% of the total intensity of the beam in the focal plane;
the second half-plane does not overlap the first half-plane;
the second interaction length is a distance, measured along a second direction different from the first direction, between a third straight line and a fourth straight line;
the third straight line is perpendicular to the second direction;
the fourth straight line is perpendicular to the second direction;
the third straight line defines a third half-plane;
the third half-plane is in the focal plane and contains 25% of the total intensity of the beam in the focal plane;
the fourth straight line defines a fourth half-plane;
the fourth half-plane is in the focal plane;
the fourth half-plane and contains 25% of the total intensity of the beam in the focal plane; and
the fourth half-plane and does not overlap the third half-plane.

2. The method of claim 1, wherein g) comprises:
weighting the recorded images using non-uniform weight distributions, wherein orientations of the weight distributions are selected to correspond to the target orientations; and
merging the weighted images.

3. The method of claim 2, wherein:
the weight distributions wᵢ(\vec{k}) fulfil wᵢ(\vec{k}_{i,1})>wᵢ(\vec{k}_{i,2});
i represents an index identifying an i-th one of the recorded images and ranges over all of the recorded images;
wᵢ(\vec{k}_{i,1}) represents a weight for a spatial-frequency domain component of the i-th recorded image at spatial-frequency \vec{k}_{i,1};
wᵢ(\vec{k}_{i,2}) represents the weight for the spatial-frequency domain component of the i-th recorded image at spatial-frequency \vec{k}_{i,2};
\vec{k}_{i,1} represents a spatial-frequency of magnitude K in a spatial-frequency domain direction corresponding to the first direction; and
\vec{k}_{i,2} represents a spatial-frequency of magnitude K in a spatial-frequency domain direction corresponding to the second direction.

4. The method of claim 1, wherein g) comprises:
convolving the recorded images using non-uniform point spread functions, wherein orientations of the point spread functions are selected to correspond to the target orientations; and
merging the convolved images.

5. The method of claim 1, wherein the manipulating of the beam (3) (S3) comprises:
generating a first multipole field acting on the beam (3), wherein the first multipole field comprises a first electric multipole field having a four-pole component and a first magnetic multipole field having a four-pole component, wherein the first electric multipole field and the first magnetic multipole field are superimposed.

6. The method of claim 5, wherein the first multipole field:
focuses the charged particles having a kinetic energy greater than a predetermined kinetic energy in the first direction;
defocusses the charged particles having a kinetic energy less than the predetermined kinetic energy in the first direction;
defocusses the charged particles having the kinetic energy greater than the predetermined kinetic energy in the second direction; and
focuses the charged particles having the kinetic energy less than the predetermined kinetic energy in the second direction.

7. The method of claim 5, wherein the first multipole field reduces a chromatic aberration of the focusing by the objective lens in the first direction and increases the chromatic aberration of the focusing by the objective lens in the second direction.

8. The method of claim 5, wherein d) comprises rotating the first multipole field.

9. The method of claim 5, wherein, except for the first multipole field, the method comprises no other electric or magnetic fields are provided for correcting the chromatic aberration of the focusing by the objective lens in a direction different from the first direction.

10. The method of claim 5, wherein d) comprises:
adjusting a maximum illumination angle of the beam in a first plane to a first maximum illumination angle value, the first plane being perpendicular to the focal plane and including the first direction; and
adjusting a maximum illumination angle of the beam in a second plane to a second maximum illumination angle value different from the first maximum illumination angle value, the second plane being perpendicular to the focal plane and including the second direction.

11. The method of claim 10, wherein d) comprises:
using an aperture stop comprising a non-circular aperture to block a first portion of the beam; and
transmitting a second portion of the beam through the aperture of the aperture stop, the second portion of the beam being different from the first portion of the beam.

12. The method of claim 11, wherein d) comprises rotating the aperture stop.

13. The method of claim 12, wherein adjusting the maximum illumination angles comprises generating a second multipole field and a third multipole field, wherein:
the second and third multipole fields act on the beam the objective lens focuses the beam into the focal plane;
the second multipole field comprises a second electric multipole field and a second magnetic multipole field;
the second multipole field focuses the beam in the first direction with a selectable first focusing power and focuses the beam in the second direction with a selectable second focusing power different from the first focusing power;
the third multipole field comprises a third electric multipole field and a third magnetic multipole field;
the third multipole field focuses the beam in the first direction with a selectable third focusing power and focuses the beam in the second direction with a selectable fourth focusing power different from the third focusing power.

14. The method of claim 13, wherein d) comprises rotating the second multipole field and the third multipole field.

15. The method of claim 10, wherein adjusting the maximum illumination angles comprises:
generating a second multipole field acting on the beam before the objective lens focuses the beam in the focal plane;
the second multipole field comprises a second electric multipole field and a second magnetic multipole field;
the second multipole field focuses the beam in the first direction with a selectable first focusing power and focuses the beam in the second direction with a selectable second focusing power different from the first focusing power;
the first multipole field focuses the beam in the first direction with a selectable third focusing power and focuses the beam in the second direction with a selectable fourth focusing power different from the third focusing power.

16. The method of claim 15, wherein d) comprises rotating the first multipole field and the second multipole field.

17. The method of claim 13, wherein the first to fourth focusing powers are selected so that, at the objective lens, the beam appears to emerge from a single virtual source.

18. The method of claim 5, wherein c) comprises generating a fourth multipole field having an eight-pole component acting on the beam, and the fourth multipole field comprises a fourth electric multipole field comprising an eight-pole component and a fourth magnetic multipole field comprising an eight-pole component.

19. The method of claim 1, further comprising:
reducing an energy width of the beam below 0.2 eV, wherein the energy width is a difference between two kinetic energy values at which a frequency distribution of kinetic energies of the charged particles of the beam is equal to half of its maximum value;
adjusting a maximum illumination angle of the beam in a first plane to a first maximum illumination angle value, the first plane being perpendicular to the focal plane and including the first direction; and
adjusting a maximum illumination angle of the beam in a second plane to a second maximum illumination angle value different from the first maximum illumination angle value, the second plane being perpendicular to the focal plane and including the second direction.

20.-24. (canceled)

25. The method of claim 1, wherein:
d) is performed so that a ratio of a third interaction length to a fourth interaction length amounts to at most 1:1.2;
the third interaction length is a distance, measured along a third direction different from the first and second direction, between a fifth straight line and a sixth straight line;
the fifth straight line is perpendicular to the third direction;
the sixth straight line is perpendicular to the third direction;
the fifth straight line defines a fifth half-plane;
the fifth half-plane is in the focal plane;
the fifth half-plane contains 25% of the total intensity of the beam in the focal plane;
the sixth straight line defines a sixth half-plane;
the sixth half-plane is in the focal plane;
the sixth half-plane contains 25% of the total intensity of the beam in the focal plane;
the sixth half-plane and does not overlap the fifth half-plane;
the fourth interaction length is a distance, measured along a fourth direction different from the first, second and third directions, between a seventh straight line and an eighth straight line;
the seventh straight line is perpendicular to the fourth direction;
the eighth straight line is perpendicular to the fourth direction;
the seventh straight line defines a seventh half-plane;
the seventh half-plane is in the focal plane;
the seventh half-plane contains 25% of the total intensity of the beam in the focal plane;
the eighth straight line defines an eighth half-plane;
the eighth half-plane is in the focal plane;
the eighth half-plane contains 25% of the total intensity of the beam in the focal plane; and
the eighth half-plane does not overlap the sevenths half-plane.

26. (canceled)

27. (canceled)

28. The method of claim 27, wherein:
the octupole field comprises an electric multipole field comprises an eight-pole component;
the octupole field comprises a magnetic multipole field comprising an eight-pole component; and
the electric multipole field and the magnetic multipole field are superimposed.

29. The method of claim 1, wherein d) comprises rotating the sample.

30. The method of claim 1, wherein recording the image of the sample comprises:
maintaining the adjusted orientation while directing the manipulated beam to a plurality of locations of the sample;
detecting interaction products of an interaction of the manipulated beam with the sample while directing the manipulated beam to the plurality of locations of the sample; and
generating the image based on the detected interaction products.

31. One or more machine-readable hardware storage devices comprising instructions that are executable by one or more processing devices to perform operations comprising the method of claim 1.

32. A system, comprising:
one or more processing devices; and
one or more machine-readable hardware storage devices comprising instructions that are executable by the one or more processing devices to perform operations comprising the method of claim 1.

33. A method, comprising:
using a particle beam system to generate a beam of charged particles;
using an objective lens of the particle beam system to focus the beam into a focal plane;
manipulating the beam into a beam profile in which a ratio of a first interaction length to a second interaction length is at most 1:1.2;
adjusting an orientation of the beam profile in the focal plane relative to a sample to a target orientation;
recording an image of the sample located in the focal plane using the manipulated beam having the adjusted orientation; and
selecting the target orientation based on an orientation of a structure on the sample,
wherein:
the first interaction length is a distance, measured along a first direction, between a first straight line and a second straight line;
the first straight line is perpendicular to the first direction;
the second straight line is perpendicular to the first direction;
the first straight line defines a first half-plane;
the first half-plane is in the focal plane;
the first half-plane contains 25% of a total intensity of the beam in the focal plane;
the second straight line defines a second half-plane;
the second half-plane is in the focal plane;
the second half-plane contains 25% of the total intensity of the beam in the focal plane;
the second half-plane does not overlap the first half-plane;
the second interaction length is a distance, measured along a second direction different from the first direction, between a third straight line and a fourth straight line;
the third straight line is perpendicular to the second direction;
the fourth straight line is perpendicular to the second direction;
the third straight line defines a third half-plane;
the third half-plane is in the focal plane;
the third half-plane contains 25% of the total intensity of the beam in the focal plane;
the fourth straight line defines a fourth half-plane;
the fourth half-plane is in the focal plane;
the fourth half-plane contains 25% of the total intensity of the beam in the focal plane; and
the fourth half-plane does not overlap the third half-plane.

34.-36. (canceled)
